(19) United States
(12) Patent Application Publication
(10) Pub. No.: US 2025/0344414 A1
(43) Pub. Date: Nov. 6, 2025

(54) REPLACEMENT CHANNEL INTEGRATION FOR THREE DIMENSIONAL MEMORY CELL ARCHITECTURES

(71) Applicant: Micron Technology, Inc., Boise, ID (US)

(72) Inventors: Fabio Pellizzer, Boise, ID (US); Agostino Pirovano, Milano (IT); Farrell M. Good, Meridian, ID (US)

(21) Appl. No.: 18/787,638

(22) Filed: Jul. 29, 2024

Related U.S. Application Data
(60) Provisional application No. 63/641,286, filed on May 1, 2024.

(51) Int. Cl. H10B 99/00

(52) U.S. Cl. CPC H10B 99/10

(57) ABSTRACT

Methods, systems, and devices for replacement channel integration for three dimensional memory cell architectures are described. A method of manufacturing a memory architecture may include forming a stack of materials above a substrate. Trenches may be formed within the stack of materials, where each trench may include a gate oxide material lining the trench, and pairs of conductive pillars forming gate elements. The gate elements may form word lines associated with activating memory cells of the memory architecture. Another trench may be formed perpendicular to the trenches, and used for forming memory cells each including a selection element and a storage element within sacrificial layers of the stack of materials between the trenches. The trench may form a source line for accessing the memory cells adjacent to the trench. A digit line may be formed around the trenches and may be configured to access the memory cells.

### CROSS REFERENCE

The present application for patent claims priority to U.S. Patent Application No. 63/641,286 by Pellizzer et al., entitled “REPLACEMENT CHANNEL INTEGRATION FOR THREE DIMENSIONAL MEMORY CELL ARCHITECTURES,” filed May 1, 2024, which is assigned to the assignee hereof, and which is expressly incorporated by reference in its entirety herein.

### TECHNICAL FIELD

The following relates to one or more systems for memory, including replacement channel integration for three dimensional memory cell architectures.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a memory array that supports replacement channel integration for three dimensional memory cell architectures in accordance with examples as disclosed herein.

FIGS. 2A, 2B, and 2C show various views of an example of a memory array that supports replacement channel integration for three dimensional memory cell architectures in accordance with examples as disclosed herein.

FIG. 3 shows an example of a memory architecture that supports replacement channel integration for three dimensional memory cell architectures in accordance with examples as disclosed herein.

FIGS. 4A, 4B, 4C, 4D, 4E, and 4F show examples of processing steps that support replacement channel integration for three dimensional memory cell architectures in accordance with examples as disclosed herein.

FIGS. 5A, 5B, and 5C show examples of processing steps that support replacement channel integration for three dimensional memory cell architectures in accordance with examples as disclosed herein.

FIGS. 6A, 6B, and 6C show examples of processing steps that support replacement channel integration for three dimensional memory cell architectures in accordance with examples as disclosed herein.

FIGS. 7 and 8 show flowcharts illustrating a method or methods that support replacement channel integration for three dimensional memory cell architectures in accordance with examples as disclosed herein.

### DETAILED DESCRIPTION

Some memory device architectures may include word lines, digit lines, and source lines configured to support accessing associated memory cells within the memory device. In some cases, manufacturing the memory device may be associated with a relatively high quantity of processing steps, where some of the processing steps may be associated with relatively high temperatures. However, performing multiple processing steps at the relatively high temperatures may result in manufacturing memory cells that are at least partially affected (e.g., degraded) due to the relatively high temperatures. That is, the processing steps may degrade the memory cells to some degree, which may lower a resulting thermal budget sustainability of the memory cells, among other effects. In some cases, forming the memory cells relatively early in the manufacturing process may result in relatively greater channel controllability. However, in some such cases, forming the memory cells earlier in the manufacturing process may subject the memory cells to a relatively higher quantity of processing steps, resulting in relatively lower thermal budget sustainability of the memory cells.

In accordance with examples as described herein, a manufacturing process may implement an improved sequence for forming a memory device architecture. For example, manufacturing the memory device may include forming the memory cells relatively late in the manufacturing process (e.g., compared to previous implementations), which may prevent a relatively high quantity of processing steps associated with relatively high temperatures from being otherwise performed on and affecting (e.g., degrading) the memory cells. That is, forming the memory cells after forming other components of the memory architecture (e.g., channels, access lines) may prevent at least some relatively high temperature processing steps from being performed on and/or near the memory cells, thereby reducing degradation of the memory cells compared with other different processing sequences. In other examples, manufacturing the memory device may include forming a channel associated with selecting the memory cells relatively late in the manufacturing process, which may reduce a thermal budget associated with forming the memory device. Likewise, manufacturing access lines (e.g., word lines, digit lines, and source lines) relatively late in the manufacturing process may simplify the manufacturing process and provide more efficient spatial scaling, among other benefits. In some cases, the manufacturing process may include forming trenches through a stack, depositing the memory cells within the memory architecture via the trenches, forming source lines, and forming digit lines. Forming the memory cells later in the manufacturing process (e.g., compared to previous implementations) may be associated with relatively higher thermal sustainability of the memory cells, while maintaining channel controllability. Forming the access lines later in the manufacturing process (e.g., compared to previous implementations) may be associated with simplicity for implementing more efficient scaling and lower thermal consumption of the manufacturing process, which may benefit the resulting components of the memory device.

In addition to applicability in memory systems described herein, techniques for replacement channel integration for three dimensional memory cell architectures may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may improve the security of electronic devices and systems by manufacturing memory cells of the electronic devices such that the resulting memory cells may be accessed more reliably, among other benefits.

In addition to applicability in memory systems as described herein, techniques for replacement channel integration for three dimensional memory cell architectures may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by manufacturing memory cells of the electronic devices relatively later in the manufacturing process, which may impede degradation of the memory cells (e.g., otherwise caused by manufacturing the memory cells earlier in the manufacturing process), thereby extending the life of electronic devices and reducing electronic waste, among other benefits.

Features of the disclosure are illustrated and described in the context of memory devices and arrays. Features of the disclosure are further illustrated and described in the context of memory architectures, processing steps, and flowcharts.

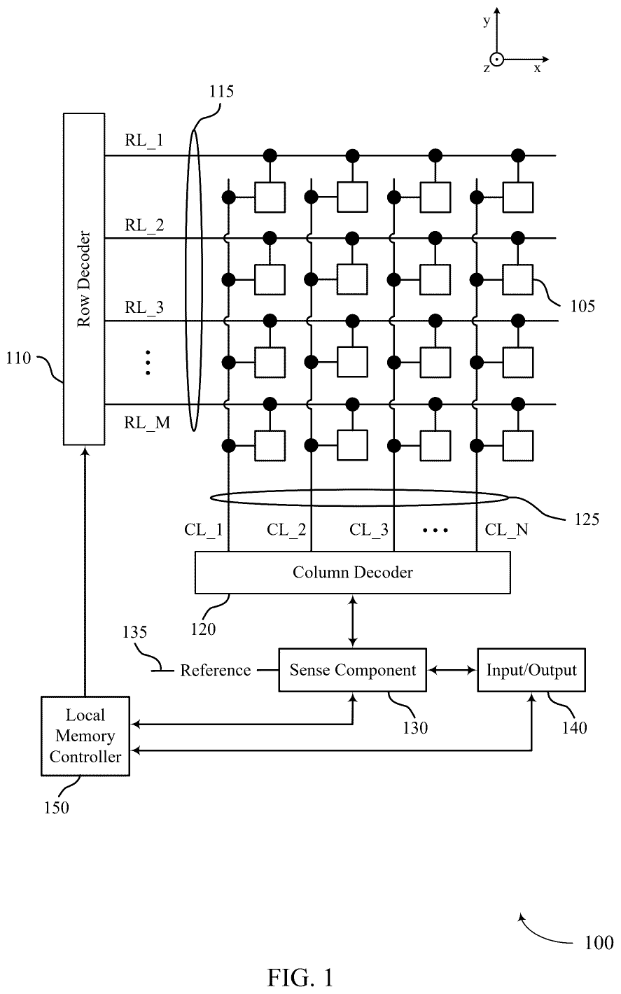

FIG. 1 shows an example of a memory device 100 that supports replacement channel integration for three dimensional memory cell architectures in accordance with examples as disclosed herein. In some examples, the memory device 100 may be referred to as or include a memory die, a memory chip, or an electronic memory apparatus. The memory device 100 may be operable to provide locations to store information (e.g., physical memory addresses) that may be used by a system (e.g., a host device coupled with the memory device 100, for writing information, for reading information).

The memory device 100 may include one or more memory cells 105 that each may be programmable to store different logic states (e.g., a programmed one of a set of two or more possible states). For example, a memory cell 105 may be operable to store one bit of information at a time (e.g., a logic 0 or a logic 1). In some examples, a memory cell 105 (e.g., a multi-level memory cell 105) may be operable to store more than one bit of information at a time (e.g., a logic 00, logic 01, logic 10, a logic 11). In some examples, the memory cells 105 may be arranged in an array.

A memory cell 105 may store a logic state using a configurable material, which may be referred to as a memory element, a storage element, a memory storage element, a material element, a material memory element, a material portion, or a polarity-written material portion, among others. A configurable material of a memory cell 105 may refer to a chalcogenide-based storage component. For example, a chalcogenide storage element may be used in a phase change memory cell, a thresholding memory cell, or a self-selecting memory cell, among other architectures.

In some examples, the material of a memory cell 105 may include a chalcogenide material or other alloy including selenium (Se), tellurium (Te), arsenic (As), antimony (Sb), carbon (C), germanium (Ge), silicon (Si), or indium (In), or various combinations thereof. In some examples, a chalcogenide material having primarily selenium (Se), arsenic (As), and germanium (Ge) may be referred to as a SAG-alloy. In some examples, a SAG-alloy may also include silicon (Si) and such chalcogenide material may be referred to as SiSAG-alloy. In some examples, SAG-alloy may include silicon (Si) or indium (In) or a combination thereof and such chalcogenide materials may be referred to as SiSAG-alloy or InSAG-alloy, respectively, or a combination thereof. In some examples, the chalcogenide material may include additional elements such as hydrogen (H), oxygen (O), nitrogen (N), chlorine (Cl), or fluorine (F), each in atomic or molecular forms.

In some examples, a memory cell 105 may be an example of a phase change memory cell. In such examples, the material used in the memory cell 105 may be based on an alloy (such as the alloys listed above) and may be operated so as to change to different physical state (e.g., undergo a phase change) during normal operation of the memory cell 105. For example, a phase change memory cell 105 may be associated with a relatively disordered atomic configuration (e.g., a relatively amorphous state) and a relatively ordered atomic configuration (e.g., a relatively crystalline state). A relatively disordered atomic configuration may correspond to a first logic state (e.g., a RESET state, a logic 0) and a relatively ordered atomic configuration may correspond to a second logic state (e.g., a logic state different than the first logic state, a SET state, a logic 1).

In some examples (e.g., for thresholding memory cells 105, for self-selecting memory cells 105), some or all of the set of logic states supported by the memory cells 105 may be associated with a relatively disordered atomic configuration of a chalcogenide material (e.g., the material in an amorphous state may be operable to store different logic states). In some examples, the storage element of a memory cell 105 may be an example of a self-selecting storage element. In such examples, the material used in the memory cell 105 may be based on an alloy (e.g., such as the alloys listed above) and may be operated so as to undergo a change to a different physical state during normal operation of the memory cell 105. For example, a self-selecting or thresholding memory cell 105 may have a high threshold voltage state and a low threshold voltage state, where a corresponding “threshold voltage” may refer to a voltage at which or above which the memory cell 105 transitions from a relatively higher-resistance (e.g., non-conductive) state to a relatively lower-resistance (e.g., conductive) state, such as in response to an applied voltage. A high threshold voltage state may correspond to a first logic state (e.g., a RESET state, a logic 0) and a low threshold voltage state may correspond to a second logic state (e.g., a logic state different than the first logic state, a SET state, a logic 1).

During a write operation (e.g., a programming operation) of a self-selecting or thresholding memory cell 105, a polarity used for a write operation may influence (e.g., determine, set, program) a behavior or characteristic of the material of the memory cell 105, such as a thresholding characteristic (e.g., a threshold voltage) of the material. A difference between thresholding characteristics (e.g., resistivity characteristics, conductivity characteristics) of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

The memory device 100 may include access lines (e.g., row lines 115 each extending along an illustrative x-direction, column lines 125 each extending along an illustrative y-direction) arranged in a pattern, such as a grid-like pattern. Access lines may be formed with one or more conductive materials. In some examples, row lines 115, or some portion thereof, may be referred to as word lines. In some examples, column lines 125, or some portion thereof, may be referred to as digit lines or bit lines. References to access lines, or their analogues, are interchangeable without loss of understanding. Memory cells 105 may be positioned at intersections of access lines, such as row lines 115 and the column lines 125. In some examples, memory cells 105 may also be arranged (e.g., addressed) along an illustrative z-direction, such as in an implementation of sets of memory cells 105 being located at different levels (e.g., layers, decks, planes, tiers) along the illustrative z-direction. In some examples, a memory device 100 that includes memory cells 105 at different levels may be supported by a different configuration of access lines, decoders, and other supporting circuitry than shown.

Operations such as read operations and write operations may be performed on the memory cells 105 by activating access lines such as one or more of a row line 115 or a column line 125, among other access lines associated with alternative configurations. For example, by activating a row line 115 and a column line 125 (e.g., applying a voltage to the row line 115 or the column line 125), a memory cell 105 may be accessed in accordance with their intersection. An intersection of a row line 115 and a column line 125, among other access lines, in various two-dimensional or three-dimensional configuration may be referred to as an address of a memory cell 105. In some examples, an access line may be a conductive line coupled with a memory cell 105 and may be used to perform access operations on the memory cell 105. In some examples, the memory device 100 may perform operations responsive to commands, which may be issued by a host device coupled with the memory device 100 or may be generated by the memory device 100 (e.g., by a local memory controller 150).

Accessing the memory cells 105 may be controlled through one or more decoders, such as a row decoder 110 or a column decoder 120, among other examples. For example, a row decoder 110 may receive a row address from the local memory controller 150 and activate a row line 115 based on the received row address. A column decoder 120 may receive a column address from the local memory controller 150 and may activate a column line 125 based on the received column address.

The sense component 130 may be operable to detect a state (e.g., a material state, a resistance state, a threshold state) of a memory cell 105 and determine a logic state of the memory cell 105 based on the detected state. The sense component 130 may include one or more sense amplifiers to convert (e.g., amplify) a signal resulting from accessing the memory cell 105 (e.g., a signal of a column line 125 or other access line). The sense component 130 may compare a signal detected from the memory cell 105 to a reference 135 (e.g., a reference voltage, a reference charge, a reference current). The detected logic state of the memory cell 105 may be provided as an output of the sense component 130 (e.g., to an input/output component 140), and may indicate the detected logic state to another component of the memory device 100 or to a host device coupled with the memory device 100.

The local memory controller 150 may control the accessing of memory cells 105 through the various components (e.g., a row decoder 110, a column decoder 120, a sense component 130, among other components). In some examples, one or more of a row decoder 110, a column decoder 120, and a sense component 130 may be co-located with the local memory controller 150. The local memory controller 150 may be operable to receive information (e.g., commands, data) from one or more different controllers (e.g., an external memory controller associated with a host device, another controller associated with the memory device 100), translate the information into a signaling that can be used by the memory device 100, perform one or more operations on the memory cells 105 and communicate data from the memory device 100 to a host device based on performing the one or more operations. The local memory controller 150 may generate row address signals and column address signals to activate access lines such as a target row line 115 and a target column line 125. The local memory controller 150 also may generate and control various signals (e.g., voltages, currents) used during the operation of the memory device 100. In general, the amplitude, the shape, or the duration of an applied signal discussed herein may be varied and may be different for the various operations discussed in operating the memory device 100.

The local memory controller 150 may be operable to perform one or more access operations on one or more memory cells 105 of the memory device 100. Examples of access operations may include a write operation, a read operation, a refresh operation, a precharge operation, or an activate operation, among others. In some examples, access operations may be performed by or otherwise coordinated by the local memory controller 150 in response to access commands (e.g., from a host device). The local memory controller 150 may be operable to perform other access operations not listed here or other operations related to the operating of the memory device 100 that are not directly related to accessing the memory cells 105.

In accordance with examples as described herein, a manufacturing process may implement an improved sequence for forming the memory device 100. For example, manufacturing the memory device 100 may include forming the memory cells 105 relatively late in the manufacturing process (e.g., compare to previous implementations), which may prevent a relatively high quantity of processing steps associated with relatively high temperatures from being otherwise performed on and affecting (e.g., degrading) the memory cells 105. That is, forming the memory cells 105 after forming other components of the memory architecture (e.g., channels, access lines) may prevent some relatively high temperature processing steps from being performed near the memory cells 105, thereby reducing degradation of the memory cells 105 as compared with other processing sequences. In other examples, manufacturing the memory device 100 may include forming a channel associated with selecting the memory cells 105 relatively late in the manufacturing process, which may reduce a thermal budget associated with forming the memory device 100. Likewise, manufacturing access lines (e.g., word lines, digit lines, and source lines) relatively late in the manufacturing process may simplify the manufacturing process and provide more efficient spatial scaling. In some cases, the manufacturing process may include forming trenches through a stack, depositing the memory cells 105 within the memory architecture via the trenches, forming source lines, and forming digit lines. Forming the memory cells 105 later in the manufacturing process (e.g., compared to previous implementations) may be associated with relatively higher thermal sustainability of the memory cells 105, while maintaining channel controllability. Forming the access lines later in the manufacturing process (e.g., compared to previous implementations) may be associated with simplicity for implementing more efficient scaling and lower thermal consumption of the manufacturing process, which may benefit the resulting components of the memory device 100.

The memory device 100 may include any quantity of non-transitory computer readable media that support replacement channel integration for three dimensional memory cell architectures. For example, a local memory controller 150, a row decoder 110, a column decoder 120, a sense component 130, or an input/output component 140, or any combination thereof may include or may access one or more non-transitory computer readable media storing instructions (e.g., firmware) for performing the functions ascribed herein to the memory device 100. For example, such instructions, if executed by the memory device 100, may cause the memory device 100 to perform one or more associated functions as described herein.

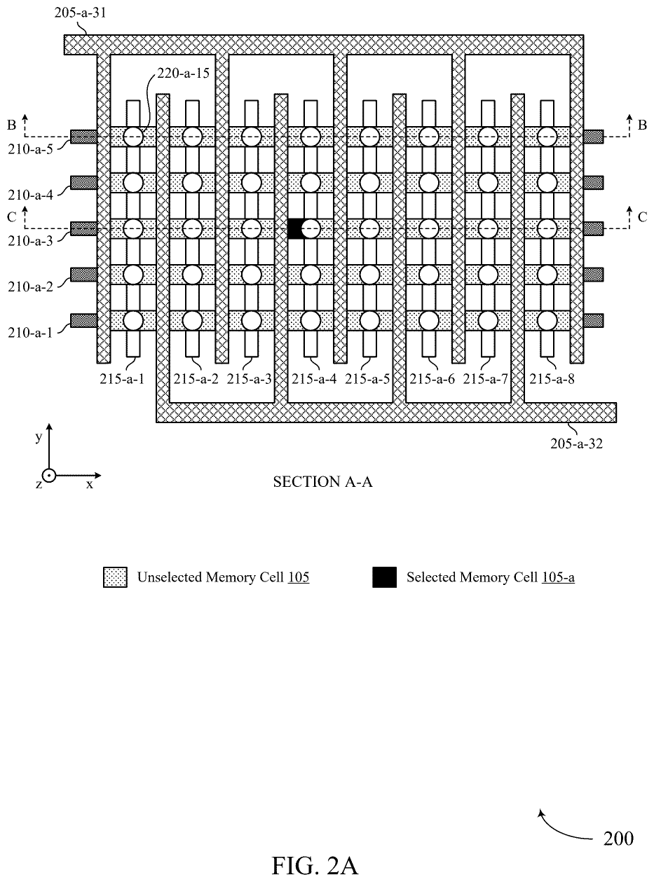

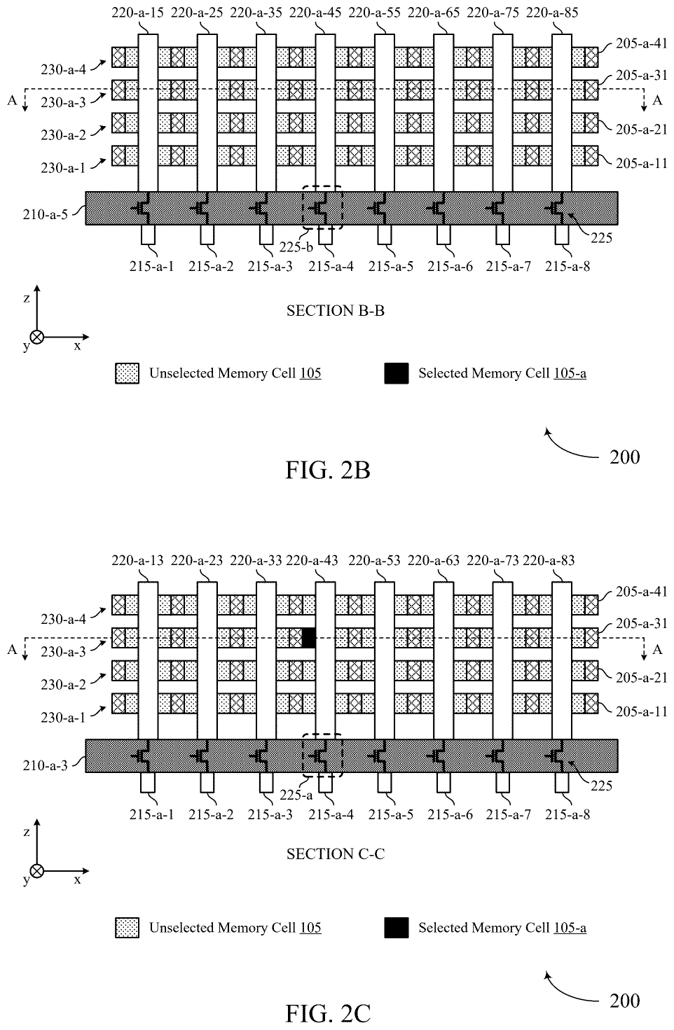

FIGS. 2A, 2B, and 2C show an example of a memory array 200 that supports replacement channel integration for three dimensional memory cell architectures in accordance with examples as disclosed herein. The memory array 200 may be included in a memory device 100, and illustrates an example of a three-dimensional arrangement of memory cells 105 that may be accessed by various conductive structures (e.g., access lines). FIG. 2A illustrates a top section view (e.g., SECTION A-A) of the memory array 200 relative to a cut plane A-A as shown in FIGS. 2B and 2C. FIG. 2B illustrates a side section view (e.g., SECTION B-B) of the memory array 200 relative to a cut plane B-B as shown in FIG. 2A. FIG. 2C illustrates a side section view (e.g., SECTION C-C) of the memory array 200 relative to a cut plane C-C as shown in FIG. 2A. The section views may be examples of cross-sectional views of the memory array 200 with some aspects (e.g., dielectric structures) removed for clarity. Elements of the memory array 200 may be described relative to an x-direction, a y-direction, and a z-direction, as illustrated in each of FIGS. 2A, 2B, and 2C. Although some elements included in FIGS. 2A, 2B, and 2C are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 200, techniques in accordance with examples as described herein may be applicable to any quantity of such elements, or ratios of quantities between one repeated element and another.

In the example of memory array 200, memory cells 105 and word lines 205 may be distributed along the z-direction according to levels 230 (e.g., decks, layers, planes, tiers, as illustrated in FIGS. 2B and 2C). In some examples, the z-direction may be orthogonal to a substrate (not shown) of the memory array 200, which may be below the illustrated structures along the z-direction. Although the illustrative example of memory array 200 includes four levels 230, a memory array 200 in accordance with examples as disclosed herein may include any quantity of one or more levels 230 (e.g., 64 levels, 128 levels) along the z-direction.

Each word line 205 may be an example of a portion of an access line that is formed by one or more conductive materials (e.g., one or more metal portions, one or more metal alloy portions). As illustrated, a word line 205 may be formed in a comb structure, including portions (e.g., projections, tines) extending along the y-direction through gaps (e.g., alternating gaps) between pillars 220. For example, as illustrated, the memory array 200, may include two word lines 205 per level 230 (e.g., according to odd word lines 205-a-n1 and even word lines 205-a-n2 for a given level, n), where such word lines 205 of the same level 230 may be described as being interleaved (e.g., with portions of an odd word line 205-a-n1 projecting along the y-direction between portions of an even word line 205-a-n2, and vice versa). In some examples, an odd word line 205 (e.g., of a level 230) may be associated with a first memory cell 105 on a first side (e.g., along the x-direction) of a given pillar 220 and an even word line (e.g., of the same level 230) may be associated with a second memory cell 105 on a second side (e.g., along the x-direction, opposite the first memory cell 105) of the given pillar 220. Thus, in some examples, memory cells 105 of a given level 230 may be addressed (e.g., selected, activated) in accordance with an even word line 205 or an odd word line 205.

Each pillar 220 may be an example of a portion of an access line (e.g., a conductive pillar portion) that is formed by one or more conductive materials (e.g., one or more metal portions, one or more metal alloy portions). As illustrated, the pillars 220 may be arranged in a two-dimensional array (e.g., in an xy-plane) having a first quantity of pillars 220 along a first direction (e.g., eight pillars along the x-direction, eight rows of pillars), and having a second quantity of pillars 220 along a second direction (e.g., five pillars along the y-direction, five columns of pillars). Although the illustrative example of memory array 200 includes a two-dimensional arrangement of eight pillars 220 along the x-direction and five pillars 220 along the y-direction, a memory array 200 in accordance with examples as disclosed herein may include any quantity of pillars 220 along the x-direction and any quantity of pillars 220 along the y-direction. Further, as illustrated, each pillar 220 may be coupled with a respective set of memory cells 105 (e.g., along the z-direction, one or more memory cells 105 for each level 230). A pillar 220 may have a cross-sectional area in an xy-plane that extends along the z-direction. Although illustrated with a circular cross-sectional area in the xy-plane, a pillar 220 may be formed with a different shape, such as having an elliptical, square, rectangular, polygonal, or other cross-sectional area in an xy-plane.

The memory cells 105 each may include a chalcogenide material. In some examples, the memory cells 105 may be examples of thresholding memory cells. Each memory cell 105 may be accessed (e.g., addressed, selected) according to an intersection between a word line 205 (e.g., a level selection, which may include an even or odd selection within a level 230) and a pillar 220. For example, as illustrated, a selected memory cell 105-a of the level 230-a-3 may be accessed according to an intersection between the pillar 220-a-43 and the word line 205-a-32.

A memory cell 105 may be accessed (e.g., written to, read from) by applying an access bias (e.g., an access voltage, V_{access}, which may be a positive voltage or a negative voltage) across the memory cell 105. In some examples, an access bias may be applied by biasing a selected word line 205 with a first voltage (e.g., V_{access}/2) and by biasing a selected pillar 220 with a second voltage (e.g., −V_{access}/2), which may have an opposite sign relative to the first voltage. Regarding the selected memory cell 105-a, a corresponding access bias (e.g., the first voltage) may be applied to the word line 205-a-32, while other unselected word lines 205 may be grounded (e.g., biased to OV). In some examples, a word line bias may be provided by a word line driver (not shown) coupled with one or more of the word lines 205.

To apply a corresponding access bias (e.g., the second voltage) to a pillar 220, the pillars 220 may be configured to be selectively coupled with a sense line 215 (e.g., a digit line, a column line, an access line extending along the y-direction) via a respective transistor 225 coupled between (e.g., physically, electrically) the pillar 220 and the sense line 215. In some examples, the transistors 225 may be vertical transistors (e.g., transistors having a channel along the z-direction, transistors having a semiconductor junction along the z-direction), which may be formed above the substrate of the memory array 200 using various techniques (e.g., thin film techniques). In some examples, a selected pillar 220, a selected sense line 215, or a combination thereof may be an example of a selected column line 125 described with reference to FIG. 1 (e.g., a bit line).

The transistors 225 (e.g., a channel portion of the transistors 225) may be activated by gate lines 210 (e.g., activation lines, selection lines, a row line, an access line extending along the x-direction) coupled with respective gates of a set of the transistors 225 (e.g., a set along the x-direction). In other words, each of the pillars 220 may have a first end (e.g., towards the negative z-direction, a bottom end) configured for coupling with an access line (e.g., a sense line 215). In some examples, the gate lines 210, the transistors 225, or both may be considered to be components of a row decoder 110 (e.g., as pillar decoder components). In some examples, the selection of (e.g., biasing of) pillars 220, or sense lines 215, or various combinations thereof, may be supported by a column decoder 120, or a sense component 130, or both.

To apply the corresponding access bias (e.g., −V_{access}/2) to the pillar 220-a-43, the sense line 215-a-4 may be biased with the access bias, and the gate line 210-a-3 may be grounded (e.g., biased to OV) or otherwise biased with an activation voltage. In an example where the transistors 225 are n-type transistors, the gate line 210-a-3 being biased with a voltage that is relatively higher than the sense line 215-a-4 may activate the transistor 225-a (e.g., cause the transistor 225-a to operate in a conducting state), thereby coupling the pillar 220-a-43 with the sense line 215-a-4 and biasing the pillar 220-a-43 with the associated access bias. However, the transistors 225 may include different channel types, or may be operated in accordance with different biasing schemes, to support various access operations.

In some examples, unselected pillars 220 of the memory array 200 may be electrically floating when the transistor 225-a is activated, or may be coupled with another voltage source (e.g., grounded, via a high-resistance path, via a leakage path) to avoid a voltage drift of the pillars 220. For example, a ground voltage being applied to the gate line 210-a-3 may not activate other transistors coupled with the gate line 210-a-3, because the ground voltage of the gate line 210-a-3 may not be greater than the voltage of the other sense lines 215 (e.g., which may be biased with a ground voltage or may be floating). Further, other unselected gate lines 210, including gate line 210-a-5 as shown in FIG. 2B, may be biased with a voltage equal to or similar to an access bias (e.g., −V_{access}/2, or some other negative bias or bias relatively near the access bias voltage), such that transistors 225 along an unselected gate line 210 are not activated. Thus, the transistor 225-b coupled with the gate line 210-a-5 may be deactivated (e.g., operating in a non-conductive state), thereby isolating the voltage of the sense line 215-a-4 from the pillar 220-a-45, among other pillars 220.

In a write operation, a memory cell 105 may be written to by applying a write bias (e.g., where V_{access}=V_{write}, which may be a positive voltage or a negative voltage) across the memory cell 105. In some examples, a polarity of a write bias may influence (e.g., determine, set, program) a behavior or characteristic of the material of the memory cell 105, such as the threshold voltage of the material. For example, applying a write bias with a first polarity may set the material of the memory cell 105 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

In a read operation, a memory cell 105 may be read from by applying a read bias (e.g., where V_{access}=V_{read}, which may be a positive voltage or a negative voltage) across the memory cell 105. In some examples, a logic state of the memory cell 105 may be evaluated based on whether the memory cell 105 thresholds (e.g., transitions to a relatively lower-resistance or conductive state, permits current) in the presence of the applied read bias. For example, such a read bias may cause a memory cell 105 storing a first logic state (e.g., a logic 0) to threshold (e.g., permit a current flow, permit a current above a threshold current), and may not cause a memory cell 105 storing a second logic state (e.g., a logic 1) to threshold (e.g., may not permit a current flow, may permit a current below a threshold current).

In accordance with examples as described herein, a manufacturing process may implement an improved sequence for forming the memory array 200. For example, manufacturing the memory array 200 may include forming the memory cells 105 relatively later in the manufacturing process, which may prevent a relatively high quantity of processing steps associated with relatively high temperatures from being otherwise performed on the memory cells 105. That is, forming the memory cells 105 after forming other components of the memory array 200 may prevent some relatively high temperature processing steps from being performed nearby the memory cells 105, which may otherwise result in degradation of the memory cells 105. In some cases, the manufacturing process may include forming trenches through a stack, depositing the memory cells 105 within the memory array 200 via the trenches, forming source lines, and forming digit lines. Forming the memory cells 105 later in the manufacturing process may be associated with relatively higher thermal sustainability of the memory cells 105, while maintaining channel controllability.

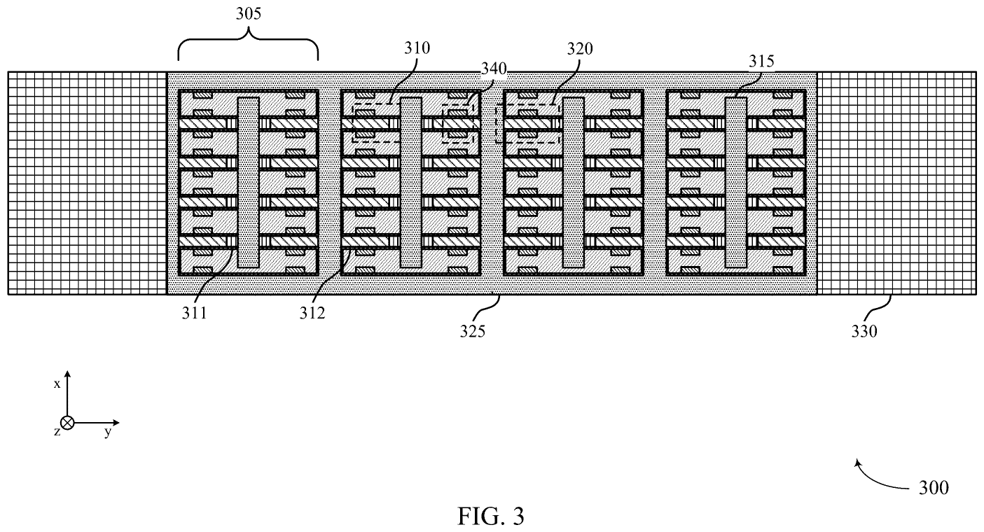

FIG. 3 shows an example of a memory architecture 300 that supports replacement channel integration for three dimensional memory cell architectures in accordance with examples as disclosed herein. The memory architecture 300 may be implemented by a memory device within a memory array, which may be examples of a memory device 100 and a memory array 200, as described with reference to FIGS. 1 through 2C. For illustrative purposes, aspects of the memory architecture 300 may be described with reference to an x-direction, a y-direction, and a z-direction of the illustrated coordinate systems. For example, FIG. 3 illustrates the memory architecture 300 from a top view in an xy-plane, where the memory architecture 300 extends a distance in the z-direction into the page. Although the memory architecture 300 illustrates examples of relative dimensions and quantities of various features, aspects of the memory architecture 300 may be implemented with other relative dimensions or quantities of such features in accordance with examples as disclosed herein.

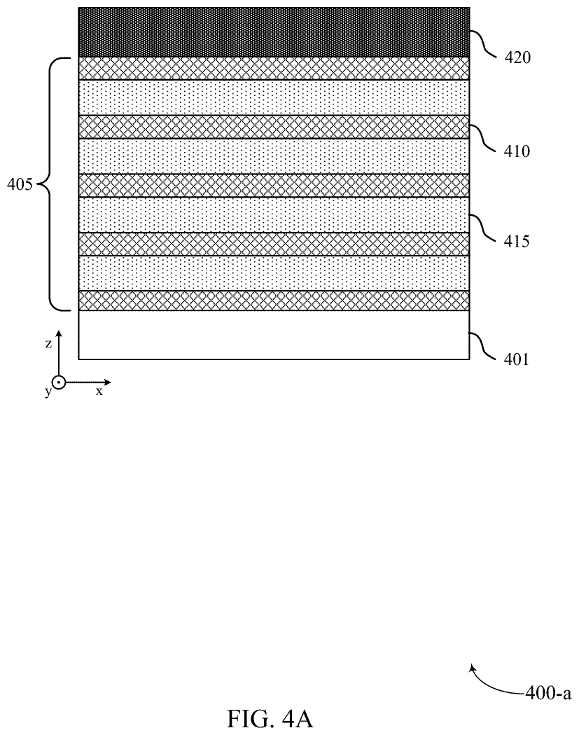

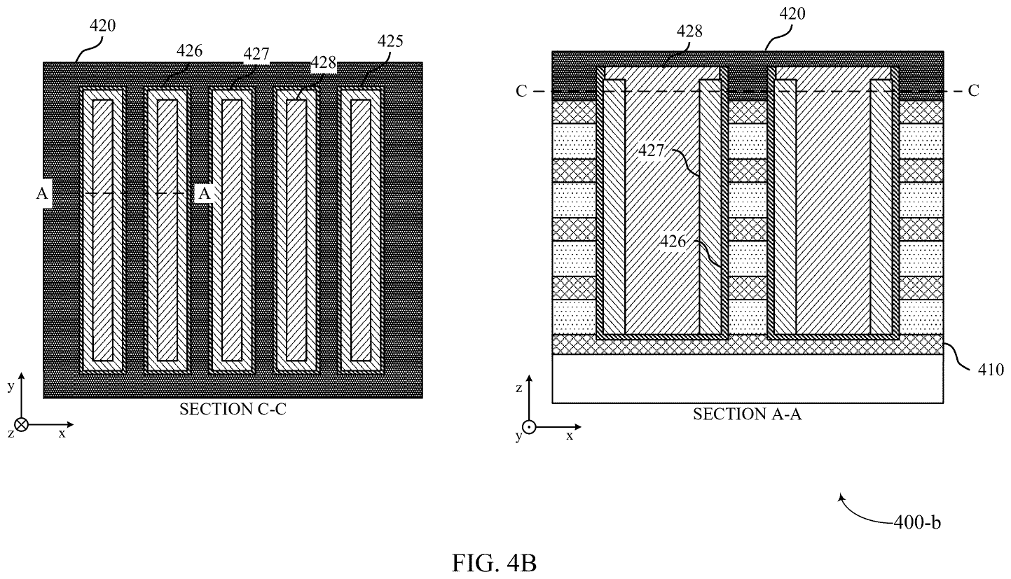

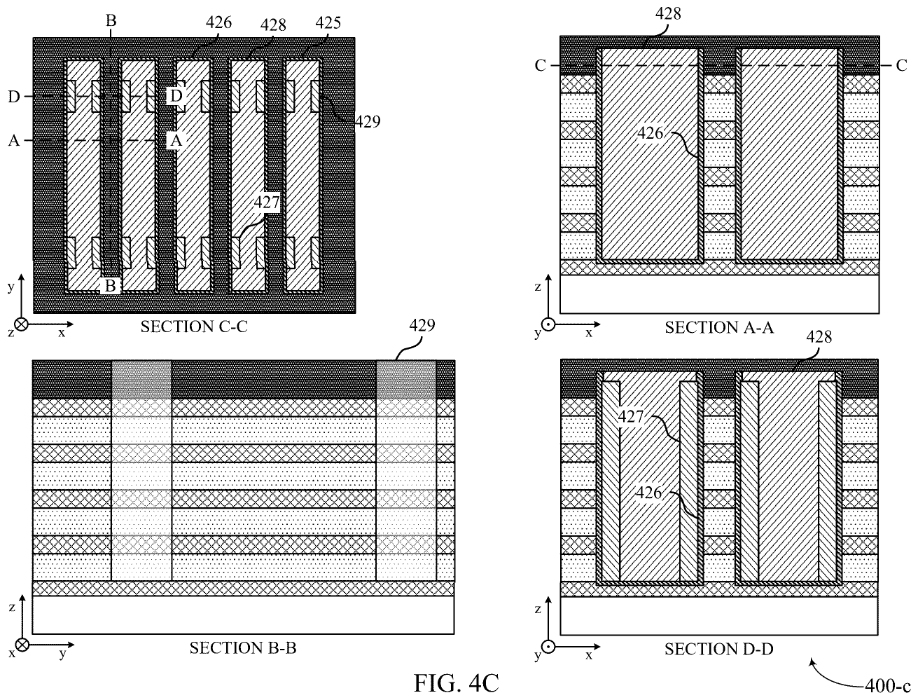

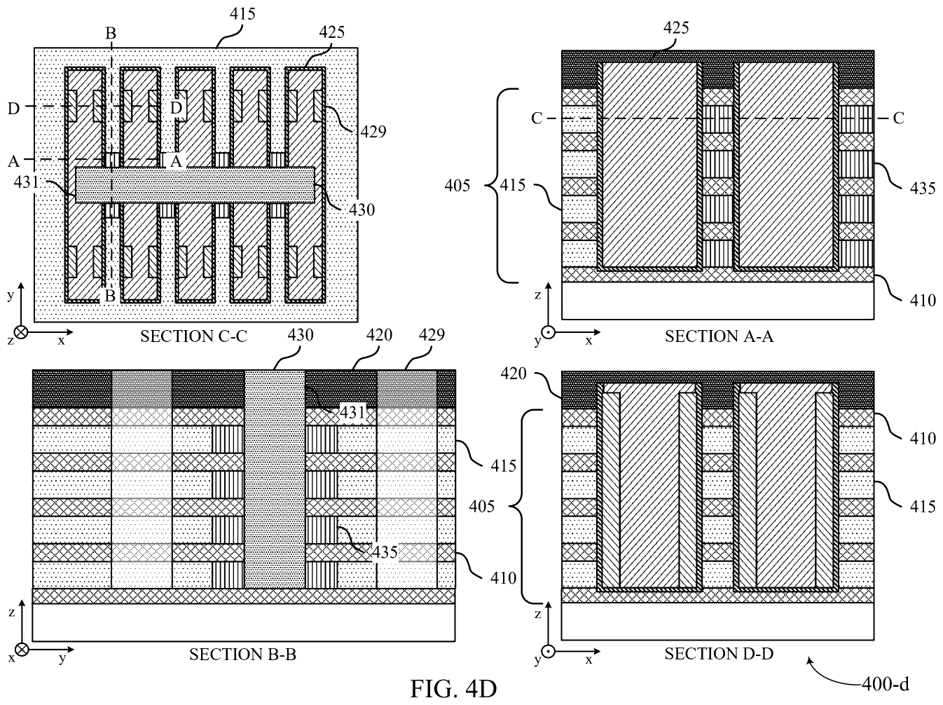

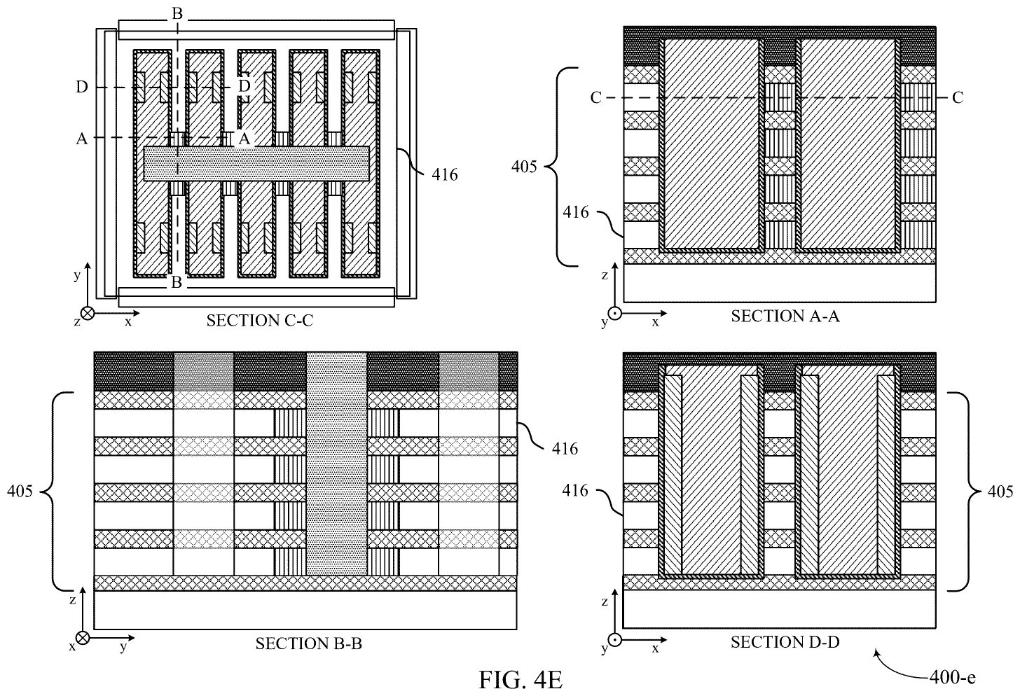

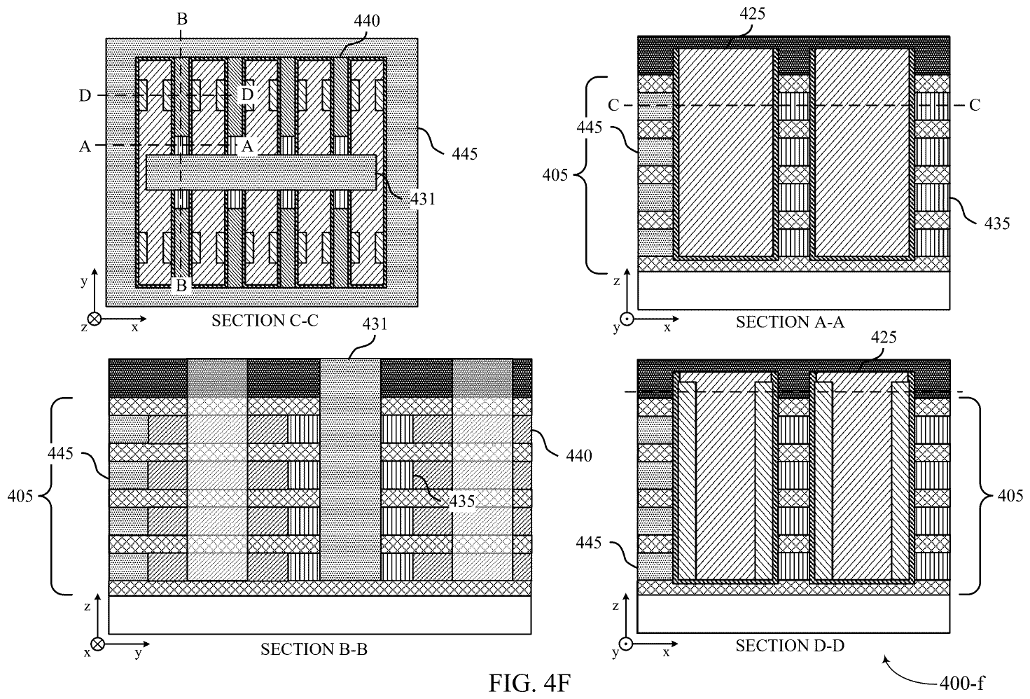

The memory architecture 300 may include a quantity of blocks 305 stacked above a substrate (e.g., not shown, for illustrative clarity) along the z-direction. For example, FIG. 3 illustrates the memory architecture 300 including four blocks 305 arranged along the y-direction, which may be a non-limiting example quantity of blocks 305. The blocks 305 may be formed from a stack of materials including alternating layers (e.g., along the z-direction) of dielectric material and at least partially conductive material, as described in further detail elsewhere herein, including with reference to FIGS. 4A through 6C. Each block 305 may include a quantity of memory cells 310 positioned adjacent to a common source line 315 of the block 305. That is, each block 305 may include a source line 315, which may be a conductive pillar associated with activating the memory cells 310 of the block 305. The memory cells 310 may be formed adjacent to the source line 315 along the y-direction and may be positioned along the source line 315 in the x-direction and the z-direction. For example, each memory cell 310 may be associated with (e.g., included in) a respective pillar 320 of the block 305, where the pillar 320 extends parallel to the source line 315 in the z-direction and is adjacent to the source line 315 (e.g., in the y-direction). That is, each pillar 320 may include a subset of memory cells 310, where each memory cell 310 of the pillar may be located at a respective layer of the stack of materials.

Each memory cell 310 may include a storage element 311 configured to store information (e.g., logic states, data). Each memory cell 310 may be associated with a selection element coupled with the storage element 311 and associated with activating the memory cell 310 (e.g., via selecting the storage element 311). The selection element may include a channel 312 extending along the y-direction, and coupled with a pair of gate elements 340. The gate elements 340 may be conductive pillars extending along the z-direction and adjacent to the channel along the x-direction. The gate elements 340 may form a word line associated with the respective memory cell 310, such that activating the word line may activate the selection element associated with the respective memory cell 310. In some cases, the selection element may include a source coupled with the digit line 325, and a drain coupled with the respective storage element.

Each block 305 may be associated with common digit lines 325. That is, the digit line 325 may be associated with each block 305 of FIG. 3. The digit line 325 illustrated in FIG. 3 may be disposed above the substrate and may extend throughout an xy-plane. The digit line 325 may be one of a quantity of digit lines 325 each associated with a respective xy-plane along the z-direction. Each digit line 325 may be associated with activating memory cells 310 at the respective layer of the digit line 325. Additionally, the digit lines 325 may be arranged around the blocks 305 in the x-direction and between each block 305 in the y-direction. The digit lines 325 may be coupled with circuitry under array (CUA) of the memory architecture 300 via one or more staircase regions 330. That is, the memory architecture 300 may include circuitry associated with operating the memory architecture 300 positioned beneath the blocks 305. In some cases, the CUA may include components associated with decoding elements of the memory architecture. For example, the CUA may include digit line decoders associated with activating the digit line 325s. The digit lines 325 may be coupled with the digit line decoders via circuitry in the staircase region 330, which may be positioned adjacent to the digit lines 325 along the y-direction.

Accessing a target memory cell 310 may include activating the digit line 325 at a same level of the memory device as the target memory cell 310, a source line 315 associated with the block 305 that includes the target memory cell 310, and a word line that is coupled with the target memory cell 310. For example, accessing a memory cell 310 may include activating the digit line 325 at a given level, which may include activating the digit line decoder coupled with the digit line 325 via the staircase region 330. In some such examples, activating the digit line 325 may include applying a voltage to the digit line 325 via the digit line decoder. Concurrently with activating the digit line 325, the source line 315 may be selected and activated to select a block 305 associated with the target memory cell 310. Likewise, a word line associated with the selected memory cell 310 may be activated, which may include activating the gate elements associated with the memory cell 310. Activating the gate elements may allow voltage to be transferred from the digit line 325 to the storage element via the selection element. In some cases, a magnitude of the voltage may be associated with information stored to the storage element 311 based on activating the digit line 325, the source line 315, and the word line associated with the memory cell 310. For example, based on activating the gate elements, the selection element may be coupled with the digit line 325 and may receive the voltage from the digit line 325 via the source of the selection element. The voltage may be transferred the selection element through the channel 312 to the storage element 311 via the drain of the selection element.

In some cases, the staircase regions 330 may be implemented in various arrangements within the memory architecture 300. For example, the staircase regions 330 are illustrated in FIG. 3 as being located adjacent to the blocks 305 in the y-direction. However, in other examples, the staircase regions 330 may be located adjacent to the blocks 305 in the x-direction. Likewise, the staircase regions 330 may be associated with supporting the quantity of blocks 305 by providing supporting circuitry (e.g., digit line decoders) to components of the blocks 305 (e.g., digit lines 325). Though FIG. 3 illustrates the staircase regions 330 supporting four blocks 305, it should be understood that the staircase regions 330 may be configured to support a quantity of blocks 305 (e.g., not limited to four blocks 305). In some cases, the quantity of blocks 305 supported by the staircase regions 330 may dictate an area efficiency of the memory architecture 300, such that an increase to the quantity of blocks 305 may be associated with increasing a quantity of tiers of the memory architecture 300.

FIGS. 4A through 4F show examples of processing steps 400 that support replacement channel integration for three dimensional memory cell architectures in accordance with examples as disclosed herein. FIGS. 4A through 4F show various cross-sectional views of a memory architecture, which may be an example of a memory architecture 300, as described with reference to FIG. 3. The processing steps 400 may illustrate aspects of manufacturing operations for fabricating aspects of memory architecture, which may be implemented in a memory device or a memory array, such as a memory device 100 and a memory array 200, as described with reference to FIGS. 1 and 2, respectively.

For illustrative purposes, aspects of the memory architecture may be described with reference to an x-direction, a y-direction, and a z-direction of the illustrated coordinate systems. For example, processing steps 400-a, 400-b, 400-c, 400-d, 400-e, and 400-f illustrate the memory architecture from various cross-sectional views (e.g., Section A-A, Section B-B, Section C-C, Section D-D) in xz-planes, xy-planes, and yz-planes, where the memory architecture extends a distance along the x-direction, the y-direction, or the z-direction into the page. Although the processing steps 400 illustrate examples of relative dimensions and quantities of various features, aspects of the memory cell structure may be implemented with other relative dimensions or quantities of such features in accordance with examples as disclosed herein. In the following description of the processing steps 400, some methods, techniques, processes, and operations may be performed in different orders or at different times. Further, some operations may be left out of the processing steps 400, or other operations may be added to the processing steps 400. The processing steps 400 may illustrate operations associated with forming memory cells relatively later in the manufacturing of the memory architecture, while maintaining channel controllability.

Operations illustrated in and described with reference to FIGS. 4A through 4F may be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 4A illustrates a first processing step 400-a for forming a stack of materials 405. FIG. 4A illustrates a cross-sectional view of the memory device in an xz-plane after forming the stack of materials 405. For example, forming the stack of materials 405 may include depositing alternating layers of a dielectric material 410 and a sacrificial material 415 above a substrate 401. The substrate 401 may be associated with complementary metal-oxide semiconductor (CMOS) circuitry. In some cases, the substrate 401 may be associated with an xy-plane upon which materials may be formed. In some cases, depositing the alternating layers may include depositing a layer of the dielectric material 410 above the substrate 401 along the z-direction, then depositing a layer of the sacrificial material 415 above the layer of the dielectric material 410. In some such cases, the dielectric material 410 and the sacrificial material 415 may be similarly deposited to form alternating layers, where the height of the stack of materials 405 may be based on the quantity and height of each of the alternating layers. In some implementations, the dielectric material 410 may be an oxide material (e.g., or similar dielectric material), such as silicon oxide, silicon oxycarbide, silicon oxynitride, or silicon nitride. In some implementations, the sacrificial material 415 may be a variation of silicon, silicon nitride, or polysilicon, among other examples. After forming the stack of materials 405, a top layer 420 may be formed above the stack of materials 405 along the z-direction. The top layer 420 may include a carbon material, a silicon nitride material, a silicon oxide material, or any combination thereof.

FIG. 4B illustrates a second processing step 400-b for forming trenches 425 in the stack of materials 405. FIG. 4B illustrates two cross-sectional views of the memory device after forming the trenches 425. For example, FIG. 4B illustrates a plane view of the memory device (e.g., a top-down view, a bird's eye view) along the C-C cross section and a cross-sectional view of the memory device along the A-A cross-section. The trenches 425 (e.g., cavities, voids) may extend along the y-direction and the z-direction, and may be arranged along the x-direction based on a pattern. In some cases, forming the trenches 425 may include removing (e.g., etching) at least a portion of the top layer 420. Forming the trenches 425 may include removing portions of the stack of materials 405 in accordance with the pattern. For example, a mask (e.g., a photolithographic mask) may be formed above the stack of materials 405, where the mask may selectively cover the stack of materials 405 such that the mask may expose the portions of the stack of materials 405 associated with the trenches 425. In some such examples, the stack of materials 405 may be etched based on the mask, such that the portions of the stack of materials 405 exposed by the mask may be removed. In some cases, the trenches 425 may extend from the top layer 420 some distance along the z-direction into the stack of materials 405. For example, the trenches 425 may extend to a bottom layer of the dielectric material 410.

After forming the trenches 425, the trenches 425 may be lined with a gate oxide material 426. The gate oxide material 426 may be deposited in the trenches 425. For example, the trenches 425 may be at least partially filled with the gate oxide material 426, and the gate oxide material 426 may be etched to a specified thickness. The gate oxide material 426 may extend along the length of the trenches 425 in the y-direction and the z-direction, and may contact the bottom and sidewalls of the trenches 425. In some cases, etching the gate oxide material 426 within the trenches 425 to the specified thickness may leave a cavity within the trenches 425. In some cases, the gate oxide material 426 may be associated with forming gates of the memory architecture. In some implementations, the gate oxide material 426 may be a silicon oxide material, an aluminum oxide material, a hafnium oxide material, potassium hydride, or a combination thereof, among other examples.

After forming the gate oxide material 426, a conductive material 427 may be formed within the trenches 425. The conductive material 427 may be deposited in the cavity in the trenches 425. For example, the trenches 425 may be at least partially filled with the conductive material 427, and the conductive material 427 may be etched to form another liner of the conductive material 427 (e.g., etched to a different thickness than the gate oxide material 426), which may appear as two pillars extending the length of the trenches 425 from the A-A cross-section. The pillars may contact the sidewalls of the gate oxide material 426 and extend to the bottom walls of the gate oxide material 426. In some cases, forming the conductive material 427 within the trenches 425 may leave a cavity within the trenches. In some cases, the conductive material 427 may be associated with forming word lines of the memory architecture. In some implementations, the conductive material 427 may be a titanium nitride material, or another metal material.

After forming the conductive material 427, the trenches 425 may be filled with a dielectric material 428. That is, the dielectric material 428 may be deposited within the trenches 425 to fill a remaining space within the trenches 425 after forming the gate oxide material 426 and the conductive material 427. In some cases, the dielectric material 428 may extend above the conductive material 427 along the z-direction. In some implementations, the dielectric material 428 may be an oxide or a spin-on dielectric (SOD) material. After filling the trenches 425, the top layer 420 may be formed above the trenches 425. For example, the portion of the top layer 420 removed during forming the trenches 425 may be reformed (e.g., redeposited). In some cases, forming the top layer 420 may include planarizing the trenches 425 and the top layer 420 prior to reforming the top layer 420 above the trenches 425.

FIG. 4C illustrates a third processing step 400-c for removing a portion of the conductive material 427 from the trenches 425. FIG. 4C illustrates four cross-sectional views of the memory device after removing the portion of the conductive material 427 from the trenches 425. For example, FIG. 4C illustrates a plane view (e.g., in an xy-plane) of the memory device (e.g., a top-down view, a bird's eye view) along the C-C cross section, a cross-sectional view (e.g., in an xz-plane) of the memory device along the A-A cross-section, a cross-sectional view (e.g., in a yz-plane) of the memory device along the B-B cross-section, and a cross-sectional view (e.g., in an xy-plane) of the memory device along the D-D cross-section. That is, the conductive material 427 may extend along the length of the trenches 425 (e.g., in the y-direction), as illustrated in FIG. 4B, and portions of the conductive material 427 may be removed from the trenches 425 in the third processing step 400-c. For example, the conductive material 427 may be etched to remove a majority of the conductive material 427 extending along the length of the trenches 425, leaving one or more pairs of pillars 429 along sidewalls of the trenches 425. In some examples, each trench 425 may include two pairs of pillars 429, where a pair of pillars 429 may include a first portion of the conductive material 427 that extends along a portion of a first sidewall of the trench 425 in the z-direction and a second portion of the conductive material 427 that extends along a portion of a second sidewall of the trench 425 in the z-direction, where the first sidewall and the second sidewall are opposite sidewalls of the trench 425. For example, the pair of pillar 429 may be shadowed in the B-B cross-section.

In some examples, etching the conductive material 427 may include using a mask to selectively cover the conductive material 427 in the portions of the first and second sidewalls of the trench 425 for subsequent formation of the pair of pillars 429 and expose the remaining conductive material 427 during an etching operation. As such, the pair of pillars 429 may remain after the etching. After removing the portions of the conductive material 427 from the pillars 429, the trenches 425 may be filled with a dielectric material 428. That is, the dielectric material 428 may be deposited within the trenches 425 to fill a remaining space within the trenches 425 after removing the portions of the conductive material 427.

FIG. 4D illustrates a fourth processing step 400-d for forming a trench 430 in the stack of materials 405. FIG. 4D illustrates four cross-sectional views of the memory device after forming the trench 430 in the stack of materials 405. For example, FIG. 4D illustrates a plane view (e.g., in an xy-plane) of the memory device (e.g., a top-down view, a bird's eye view) along the C-C cross section (e.g., at a different position along the z-direction than FIG. 4C), a cross-sectional view (e.g., in an xz-plane) of the memory device along the A-A cross-section, a cross-sectional view (e.g., in a yz-plane) of the memory device along the B-B cross-section, and a cross-sectional view (e.g., in an xy-plane) of the memory device along the D-D cross-section. The trench 430 (e.g., a cavity, a void of material) may extend along the x-direction, and from the top layer 420 some distance along the z-direction into the stack of materials 405 (e.g., to a bottom layer of the dielectric material 410). In some cases, forming the trench 430 may include removing a portion of each trench 425 and portions of the stack of materials 405 between each trench 425. Forming the trench 430 may include removing portions of the stack of materials 405 and the trenches 425 in accordance with a pattern. For example, a mask (e.g., a photolithographic mask) may be formed above the stack of materials 405 and the trenches 425, where the mask may selectively cover the stack of materials 405 and the trenches 425 such that the mask may expose the portions of the stack of materials 405 and the portions of the trenches 425 associated with the trench 430. In some such examples, the stack of materials 405 and the trenches 425 may be etched based on the mask, such that the portions of the stack of materials 405 and the trenches 425 exposed by the mask may be removed.

After forming the trench 430, the trench 430 may be used to form storage elements associated with memory cells of the memory architecture. For example, portions of the sacrificial material 415 may be removed (e.g., exhumed) via the trench 430. That is, the portions of the sacrificial material 415, as shown by the B-B cross-section, may be associated with each layer of the sacrificial material 415 and may extend some distance along the y-direction from the trench 430. Additionally, the portions of the sacrificial material 415 may be positioned between each of the trenches 425.

After removing the portions of the sacrificial material 415, storage material may be deposited within the removed portions of the sacrificial material 415. The storage material may form storage elements 435 associated with storing information based on a voltage applied to the storage elements 435. After forming the storage elements 435, the trench 430 may be filled with a conductive material 431. Filling the trench 430 with the conductive material 431 may be associated with forming a source line of the memory architecture. That is, the conductive material 431 may facilitate access operations of memory cells of the memory architecture.

FIG. 4E illustrates a fifth processing step 400-e for removing the sacrificial material 415 from the stack of materials 405. FIG. 4E illustrates four cross-sectional views of the memory device after removing the sacrificial material 415 from the stack of materials 405. For example, FIG. 4E illustrates a plane view (e.g., in an xy-plane) of the memory device (e.g., a top-down view, a bird's eye view) along the C-C cross section, a cross-sectional view (e.g., in an xz-plane) of the memory device along the A-A cross-section, a cross-sectional view (e.g., in a yz-plane) of the memory device along the B-B cross-section, and a cross-sectional view (e.g., in an xy-plane) of the memory device along the D-D cross-section. That is, the sacrificial material 415 may be removed from the respective layers of the stack of materials 405. In some cases, removing the sacrificial material 415 from the respective layers of the stack of materials 405 may include forming cavities 416 at the respective layers. In some such cases, the cavities 416 may be formed via accessing the stack of materials 405 from an exterior side of the stack of materials 405 at the respective layers. In some cases, removing the sacrificial material 415 may include exhuming the sacrificial material 415 from the stack of materials 405. For example, the sacrificial material 415 may be selectively removed from the stack of materials 405 based on exposing the stack of materials 405 to an exhuming element associated with removing the sacrificial material 415 without removing other materials of the memory architecture.

FIG. 4F illustrates a sixth processing step 400-f for forming channels 440 within the stack of materials 405. FIG. 4F illustrates four cross-sectional views of the memory device after forming the channels 440 within the stack of materials 405. For example, FIG. 4F illustrates a plane view (e.g., in an xy-plane) of the memory device (e.g., a top-down view, a bird's eye view) along the C-C cross section, a cross-sectional view (e.g., in an xz-plane) of the memory device along the A-A cross-section, a cross-sectional view (e.g., in a yz-plane) of the memory device along the B-B cross-section, and a cross-sectional view (e.g., in an xy-plane) of the memory device along the D-D cross-section. For example, the channels 440 may be formed based on removing the sacrificial material 415 from the stack of materials 405 and at least partially replacing the sacrificial material 415 with the channels 440. That is, the channels 440 may extend some direction along the y-direction at each layer of the stack of materials 405 otherwise associated with the sacrificial material 415. The channels 440 may be positioned between the trenches 425 and adjacent to the storage elements 435 along the y-direction. The channels 440 may be associated with selection elements of the memory cells of the memory architecture. That is, the selection elements may be associated with accessing the storage elements 435, such that the channels 440 may transfer voltage from digit lines to the storage elements 435.

After forming the channels 440, a conductive material 445 may be deposited around the trenches 425. For example, the conductive material 445 may be deposited within the layers of the stack of materials 405 based on removing the sacrificial material 415 from the stack of materials 405. That is, the conductive material 445 may at least partially replace the sacrificial material 415 within the respective layers of the stack of materials 405. The conductive material 445 may be positioned adjacent to the trenches 425 along the x-direction and the y-direction, such that the conductive material 445 may surround the trenches 425. In some cases, the conductive material 445 may be associated with forming digit lines associated with accessing the memory cells of the memory architecture. In some implementations, the conductive material 445 may be similar to the conductive material 431, such that the conductive material 445 and the conductive material 431 may be a same material.

In some cases, forming the conductive material 445 may be associated with forming digit lines at the respective layers of the stack of materials 405. For example, the conductive material 445 at each layer of the stack of materials 405 may be an example of a digit line 325, as described with reference to FIG. 3. Each digit line may be associated with accessing memory cells of the memory architecture at the respective layer of the stack of materials 405.

The memory cells of the memory architecture may be formed based on forming the storage element 435, the selection element, the word lines, the source line and the digit lines. For example, the memory cell may include the storage element 435 and the selection element configured to activate the storage element 435. However, the selection element may not access the storage element without activating the digit line, the word lines, and the source line associated with the storage element. Performing the processing steps 400 may be associated with manufacturing the memory architecture such that the access lines (e.g., the digit lines, the word lines) and the channels 440 are formed later in the manufacturing process. Forming the access lines and the channels 440 later in the manufacturing process may reduce a thermal budget associated with forming the memory architecture. Likewise, forming the access lines and the channels 440 later in the manufacturing process may simplify the manufacturing process and enable more efficient spatial scaling of the memory architecture, among other benefits.

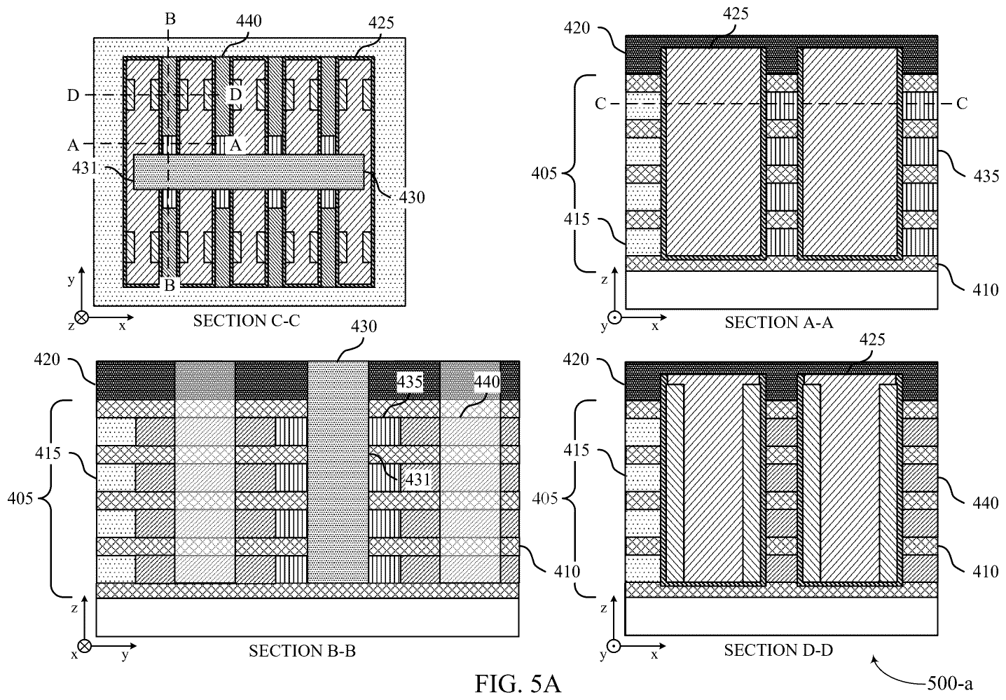

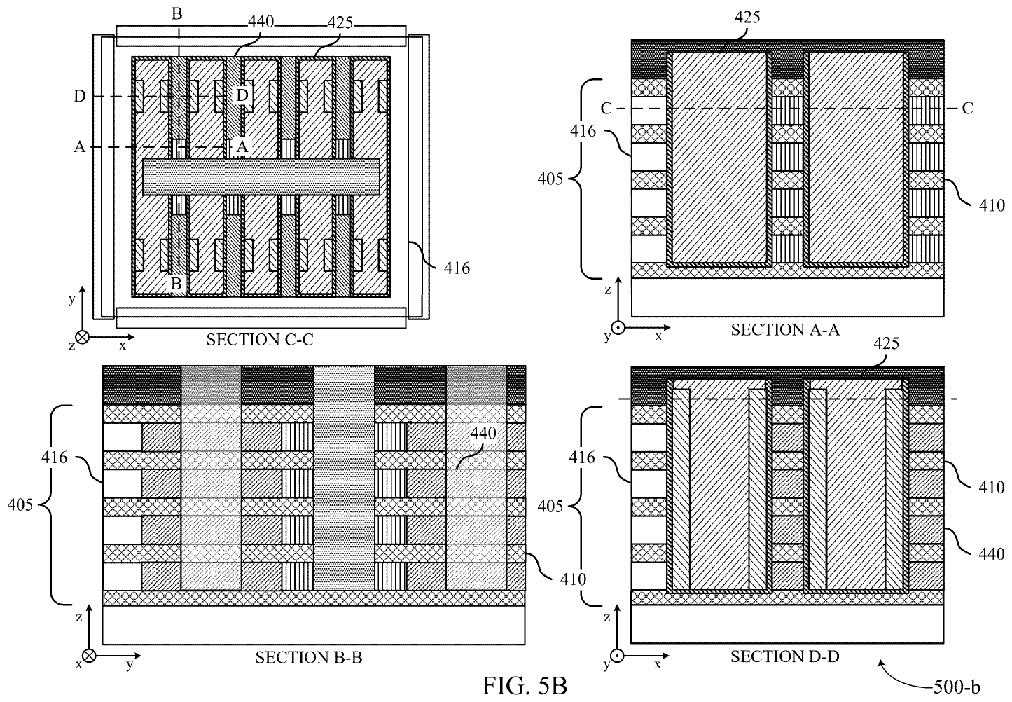

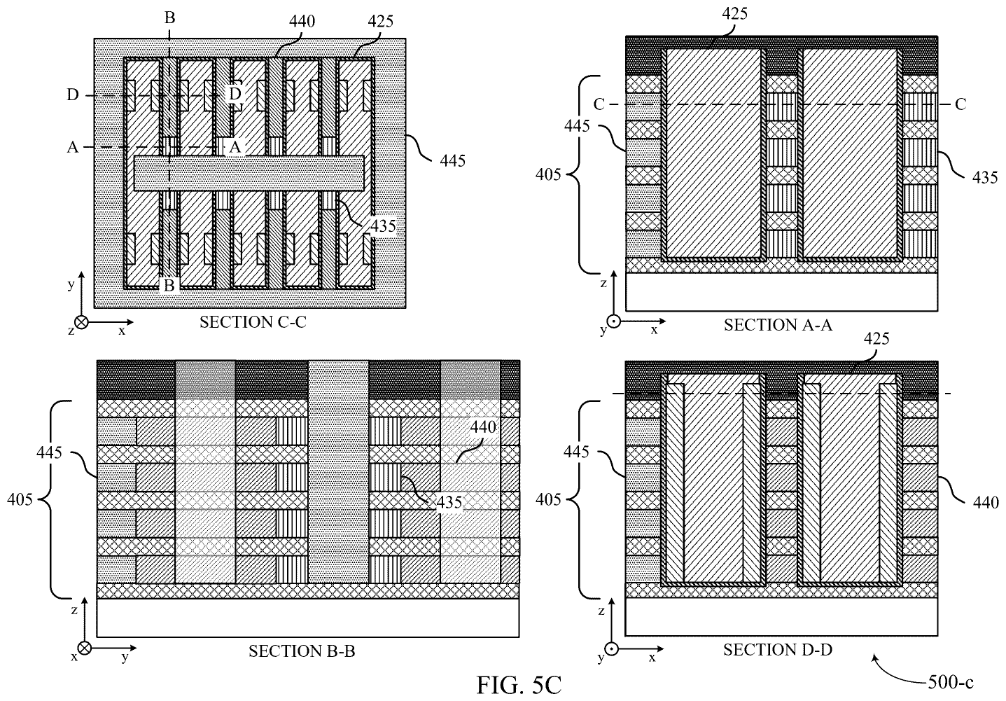

FIGS. 5A through 5C show examples of processing steps 500 that support replacement channel integration for three dimensional memory cell architectures in accordance with examples as disclosed herein. FIGS. 5A through 5C show various cross-sectional views of a memory architecture, which may be an example of a memory architecture 300, as described with reference to FIG. 3. The processing steps 500 may illustrate aspects of manufacturing operations for fabricating aspects of memory architecture, which may be implemented in a memory device or a memory array, such as a memory device 100 and a memory array 200, as described with reference to FIGS. 1 and 2, respectively.

For illustrative purposes, aspects of the memory architecture may be described with reference to an x-direction, a y-direction, and a z-direction of the illustrated coordinate systems. For example, processing steps 500-a, 500-b, and 500-c illustrate the memory architecture from various cross-sectional views (e.g., Section A-A, Section B-B, Section C-C, Section D-D) in xz-planes, xy-planes, and yz-planes, where the memory architecture extends a distance along the x-direction, the y-direction, or the z-direction into the page. Although the processing steps 500 illustrate examples of relative dimensions and quantities of various features, aspects of the memory cell structure may be implemented with other relative dimensions or quantities of such features in accordance with examples as disclosed herein. In the following description of the processing steps 500, some methods, techniques, processes, and operations may be performed in different orders or at different times. Further, some operations may be left out of the processing steps 500, or other operations may be added to the processing steps 500. The processing steps 500 may illustrate operations associated with forming memory cells relatively later in the manufacturing of the memory architecture, while maintaining channel controllability. The processing steps 500 may illustrate a different sequence of operations than the processing steps 400, but may include similar operations thereof. For example, the processing steps 400-a, 400-b, and 400-c may occur prior to the processing steps 500-a, 500-b, and 500-c. For concision, the processing steps 400-a, 400-b, and 400-c, may not be repeatedly described herein prior to the processing steps 500-a, 500-b, and 500-c. Instead, the processing steps 500-a, 500-b, and 500-c may be understood as occurring after the processing steps 400-a, 400-b, and 400-c.

Operations illustrated in and described with reference to FIGS. 5A through 5C may be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 5A illustrates a fourth processing step 500-a for forming a trench 430 in the stack of materials 405. The trench 430 may be formed after the third processing step 400-c described with reference to FIG. 4C. FIG. 5A illustrates four cross-sectional views of the memory device after forming the trench 430 in the stack of materials 405. For example, FIG. 5A illustrates a plane view (e.g., in an xy-plane) of the memory device (e.g., a top-down view, a bird's eye view) along the C-C cross section, a cross-sectional view (e.g., in an xz-plane) of the memory device along the A-A cross-section, a cross-sectional view (e.g., in a yz-plane) of the memory device along the B-B cross-section, and a cross-sectional view (e.g., in an xy-plane) of the memory device along the D-D cross-section. The trench 430 (e.g., cavities, voids) may extend along the x-direction, and from the top layer 420 some distance along the z-direction into the stack of materials 405 (e.g., to a bottom layer of the dielectric material 410). In some cases, forming the trench 430 may include removing a portion of each trench 425 and portions of the stack of materials 405 between each trench 425. Forming the trench 430 may include removing portions of the stack of materials 405 and the trenches 425 in accordance with a pattern. For example, a mask (e.g., a photolithographic mask) may be formed above the stack of materials 405 and the trenches 425, where the mask may selectively cover the stack of materials 405 and the trenches 425 such that the mask may expose the portions of the stack of materials 405 and the portions of the trenches 425 associated with the trench 430. In some such examples, the stack of materials 405 and the trenches 425 may be etched based on the mask, such that the portions of the stack of materials 405 and the trenches 425 exposed by the mask may be removed.

After forming the trench 430, at least a portion of the sacrificial material 415 may be removed from the stack of materials 405. That is, the sacrificial material 415 may be removed from the respective layers of the stack of materials 405 up to the end of the trenches 425. In some cases, removing the sacrificial material 415 may include exhuming the sacrificial material 415 from the stack of materials 405 between the trenches 425. For example, the sacrificial material 415 may be selectively removed from the stack of materials 405 based on exposing the stack of materials 405 to an exhuming element associated with removing the sacrificial material 415 without removing other materials of the memory architecture. In some cases, a duration of exposure to the exhuming element may dictate the length of the exhumation, such that exposing the stack of materials 405 to the exhuming element for the duration may exhume the sacrificial material 415 up to the end of the trenches 425.

After at least partially removing the sacrificial materials 415, channels 440 may be formed within the stack of materials 405. For example, the channels 440 may be formed based on removing the sacrificial material 415 from the stack of materials 405 and at least partially replacing the sacrificial material 415 with the channels 440. That is, the channels 440 may extend some direction along the y-direction at each layer of the stack of materials 405 otherwise associated with the sacrificial material 415. For example, the channels 440 may extend up to an end of the trenches 425 and between the trenches 425.

After forming the channels 440, storage elements 435 may be deposited within the removed portions of the sacrificial material 415. For example, the storage elements 435 may be formed within the layers otherwise associated with the sacrificial material 415 and may extend to the channels 440, such that the storage elements 435 are adjacent to the channels 440 in the y-direction. Likewise, the storage elements 435 may be deposited up to the trench 430 in the y-direction. After forming the storage elements 435, the trench 430 may be filled with a conductive material 431. Filling the trench 430 with the conductive material 431 may be associated with forming a source line of the memory architecture. For example, forming the trench 430 may be associated with forming a source line 315 associated with accessing memory cells of the memory architecture, as described with reference to FIG. 3.

FIG. 5B illustrates a fifth processing step 500-b for removing the sacrificial material 415 from the stack of materials 405. FIG. 5B illustrates four cross-sectional views of the memory device after removing the sacrificial material 415 from the stack of materials 405. For example, FIG. 5B illustrates a plane view (e.g., in an xy-plane) of the memory device (e.g., a top-down view, a bird's eye view) along the C-C cross section, a cross-sectional view (e.g., in an xz-plane) of the memory device along the A-A cross-section, a cross-sectional view (e.g., in a yz-plane) of the memory device along the B-B cross-section, and a cross-sectional view (e.g., in an xy-plane) of the memory device along the D-D cross-section. That is, the sacrificial material 415 may be removed from the respective layers of the stack of materials 405. In some cases, removing the sacrificial material 415 from the respective layers of the stack of materials 405 may include forming cavities 416 at the respective layers. In some such cases, the cavities 416 may be formed via accessing the stack of materials 405 from an exterior side of the stack of materials 405 at the respective layers. In some cases, removing the sacrificial material 415 may include exhuming the sacrificial material 415 from the stack of materials 405 around the trenches 425. For example, the sacrificial material 415 remaining around the channels 440 and the trenches 425 after forming the channels 440 may be removed from the stack of materials 405 based on exposing the stack of materials 405 to an exhuming element associated with removing the sacrificial material 415 without removing other materials of the memory architecture.

FIG. 5C illustrates a sixth processing step 500-c for forming a conductive material 445 around the trenches 425. FIG. 5C illustrates four cross-sectional views of the memory device after forming the conductive material 445 around the trenches 425. For example, FIG. 5C illustrates a plane view (e.g., in an xy-plane) of the memory device (e.g., a top-down view, a bird's eye view) along the C-C cross section, a cross-sectional view (e.g., in an xz-plane) of the memory device along the A-A cross-section, a cross-sectional view (e.g., in a yz-plane) of the memory device along the B-B cross-section, and a cross-sectional view (e.g., in an xy-plane) of the memory device along the D-D cross-section. For example, the conductive material 445 may be deposited within the layers of the stack of materials 405 based on removing the sacrificial material 415 from the stack of materials 405. That is, the conductive material 445 may at least partially replace the sacrificial material 415 within the respective layers of the stack of materials 405. The conductive material 445 may be positioned adjacent to the trenches 425 along the x-direction and the y-direction, such that the conductive material 445 may surround the trenches 425.

In some cases, forming the conductive material 445 may be associated with forming digit lines at the respective layers of the stack of materials 405. For example, the conductive material 445 at each layer of the stack of materials 405 may be an example of a digit line 325, as described with reference to FIG. 3. Each digit line may be associated with accessing memory cells of the memory architecture at the respective layer of the stack of materials 405.

The memory cells of the memory architecture may be formed based on forming the storage element 435, the selection element, the word lines, the source line and the digit lines. For example, the memory cell may include the storage element 435 and the selection element configured to activate the storage element 435. However, the selection element may not access the storage element without activating the digit line, the word lines, and the source line associated with the storage element. Performing the processing steps 400 may be associated with manufacturing the memory architecture such that the memory cells are formed later in the manufacturing process. Forming the memory cells later in the manufacturing process may prevent a relatively high quantity of relatively high temperature manufacturing operations from being performed on the memory architecture after the formation of the memory cells. Thus, the memory cells may benefit from higher thermal budget sustainability, while maintaining relatively high channel controllability.

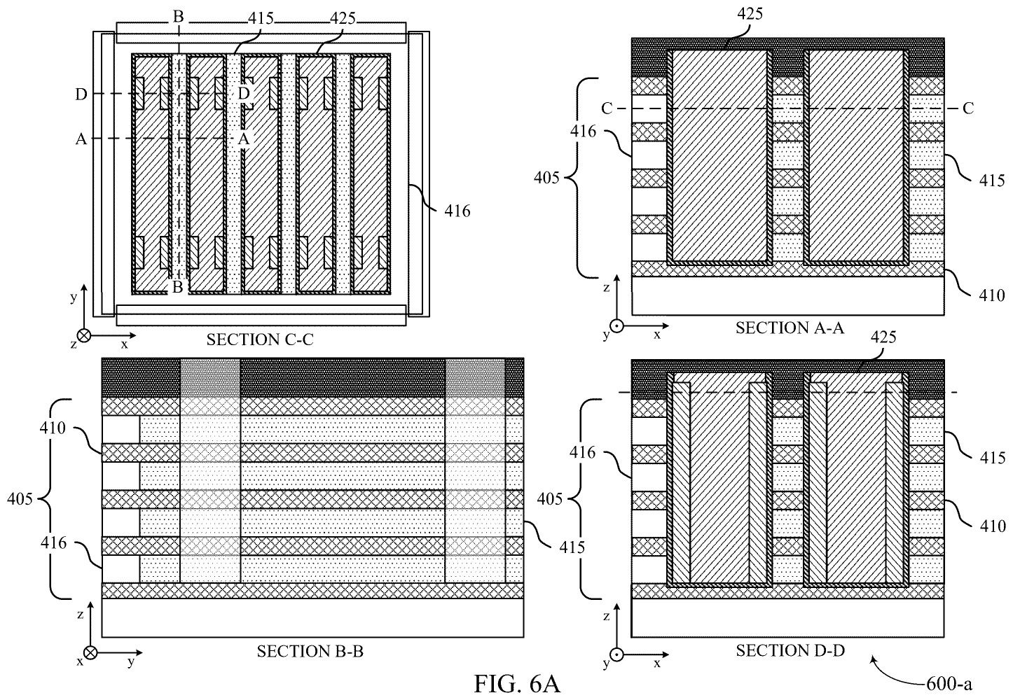

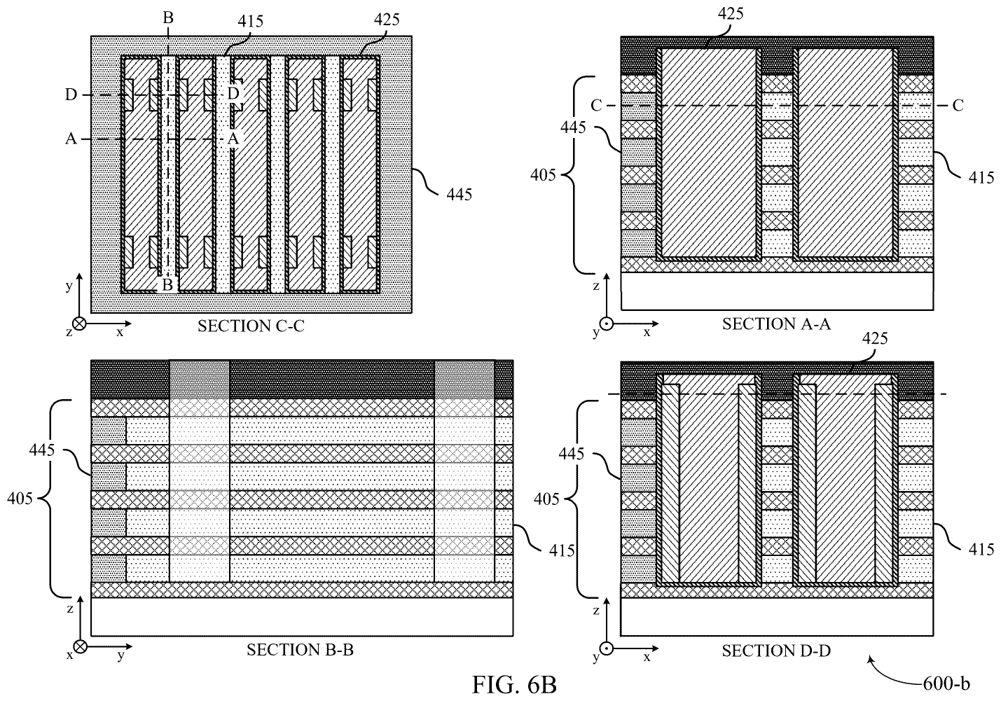

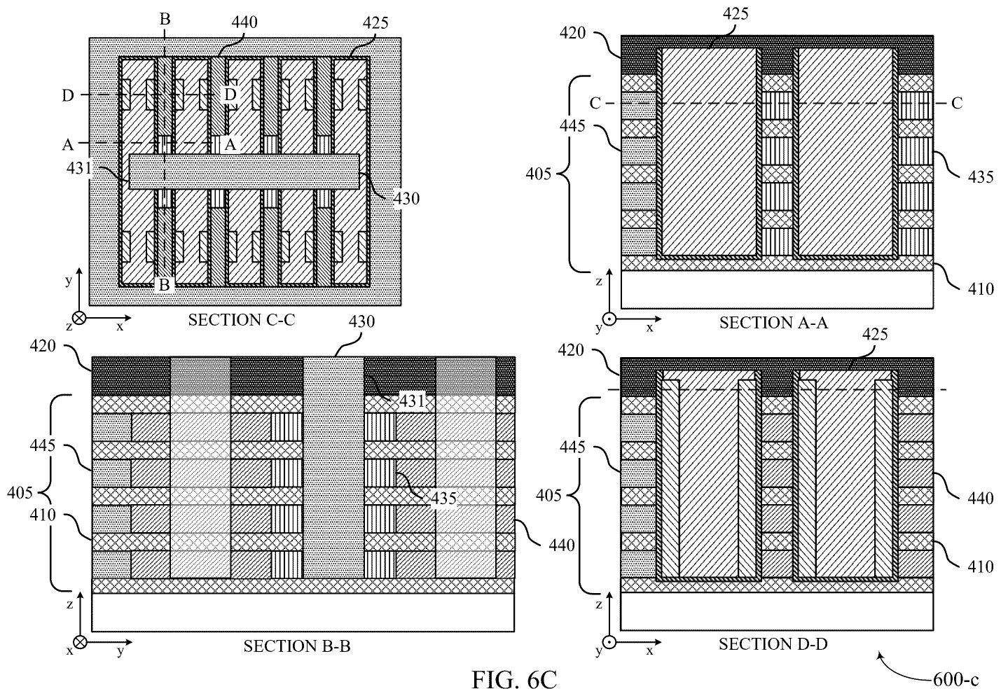

FIGS. 6A through 6C show examples of processing steps 600 that support replacement channel integration for three dimensional memory cell architectures in accordance with examples as disclosed herein. FIGS. 6A through 6C show various cross-sectional views of a memory architecture, which may be an example of a memory architecture 300, as described with reference to FIG. 3. The processing steps 600 may illustrate aspects of manufacturing operations for fabricating aspects of memory architecture, which may be implemented in a memory device or a memory array, such as a memory device 100 and a memory array 200, as described with reference to FIGS. 1 and 2, respectively.

For illustrative purposes, aspects of the memory architecture may be described with reference to an x-direction, a y-direction, and a z-direction of the illustrated coordinate systems. For example, processing steps 600-a, 600-b, and 600-c illustrate the memory architecture from various cross-sectional views (e.g., Section A-A, Section B-B, Section C-C, Section D-D) in xz-planes, xy-planes, and yz-planes, where the memory architecture extends a distance along the x-direction, the y-direction, or the z-direction into the page. Although the processing steps 600 illustrate examples of relative dimensions and quantities of various features, aspects of the memory cell structure may be implemented with other relative dimensions or quantities of such features in accordance with examples as disclosed herein. In the following description of the processing steps 600, some methods, techniques, processes, and operations may be performed in different orders or at different times. Further, some operations may be left out of the processing steps 600, or other operations may be added to the processing steps 600. The processing steps 600 may illustrate operations associated with forming memory cells relatively later in the manufacturing of the memory architecture, while maintaining channel controllability. The processing steps 600 may illustrate a different sequence of operations than the processing steps 400, but may include similar operations thereof. For example, the processing steps 400-a, 400-b, and 400-c may occur prior to the processing steps 600-a, 600-b, and 600-c. For concision, the processing steps 400-a, 400-b, and 400-c, may not be repeatedly described herein prior to the processing steps 600-a, 600-b, and 600-c. Instead, the processing steps 600-a, 600-b, and 600-c may be understood as occurring after the processing steps 400-a, 400-b, and 400-c.

Operations illustrated in and described with reference to FIGS. 6A through 6C may be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 6A illustrates a fourth processing step 600-a for removing the sacrificial material 415 from the stack of materials 405. The sacrificial material 415 may be removed from the stack of materials 405 after the third processing step 400-c described with reference to FIG. 4C. FIG. 6A illustrates four cross-sectional views of the memory device after removing the sacrificial material 415 from the stack of materials 405. For example, FIG. 6A illustrates a plane view (e.g., in an xy-plane) of the memory device (e.g., a top-down view, a bird's eye view) along the C-C cross section, a cross-sectional view (e.g., in an xz-plane) of the memory device along the A-A cross-section, a cross-sectional view (e.g., in a yz-plane) of the memory device along the B-B cross-section, and a cross-sectional view (e.g., in an xy-plane) of the memory device along the D-D cross-section. That is, the sacrificial material 415 may be removed from the respective layers of the stack of materials 405. In some cases, removing the sacrificial material 415 from the respective layers of the stack of materials 405 may include forming cavities 416 at the respective layers. In some such cases, the cavities 416 may be formed via accessing the stack of materials 405 from an exterior side of the stack of materials 405 at the respective layers. In some cases, removing the sacrificial material 415 may include exhuming the sacrificial material 415 from the stack of materials 405 around the trenches 425. For example, the sacrificial material 415 surrounding the trenches 425 may be removed from the stack of materials 405 based on exposing the stack of materials 405 to an exhuming element associated with removing the sacrificial material 415 without removing other materials of the memory architecture.

FIG. 6B illustrates a fifth processing step 600-b for forming a conductive material 445 around the trenches 425. FIG. 6B illustrates four cross-sectional views of the memory device after forming the conductive material 445 around the trenches 425. For example, FIG. 6B illustrates a plane view (e.g., in an xy-plane) of the memory device (e.g., a top-down view, a bird's eye view) along the C-C cross section, a cross-sectional view (e.g., in an xz-plane) of the memory device along the A-A cross-section, a cross-sectional view (e.g., in a yz-plane) of the memory device along the B-B cross-section, and a cross-sectional view (e.g., in an xy-plane) of the memory device along the D-D cross-section. For example, the conductive material 445 may be deposited within the layers of the stack of materials 405 based on removing the sacrificial material 415 from the stack of materials 405. That is, the conductive material 445 may at least partially replace the sacrificial material 415 within the respective layers of the stack of materials 405. The conductive material 445 may be positioned adjacent to the trenches 425 along the x-direction and the y-direction, such that the conductive material 445 may surround the trenches 425.

In some cases, forming the conductive material 445 may be associated with forming digit lines at the respective layers of the stack of materials 405. For example, the conductive material 445 at each layer of the stack of materials 405 may be an example of a digit line 325, as described with reference to FIG. 3. Each digit line may be associated with accessing memory cells of the memory architecture at the respective layer of the stack of materials 405.

FIG. 6C illustrates a sixth processing step 600-c for forming a trench 430 in the stack of materials 405. FIG. 6C illustrates four cross-sectional views of the memory device after forming the trench 430 in the stack of materials 405. For example, FIG. 6C illustrates a plane view (e.g., in an xy-plane) of the memory device (e.g., a top-down view, a bird's eye view) along the C-C cross section, a cross-sectional view (e.g., in an xz-plane) of the memory device along the A-A cross-section, a cross-sectional view (e.g., in a yz-plane) of the memory device along the B-B cross-section, and a cross-sectional view (e.g., in an xy-plane) of the memory device along the D-D cross-section. The trench 430 (e.g., cavities, voids) may extend along the x-direction, and from the top layer 420 some distance along the z-direction into the stack of materials 405 (e.g., to a bottom layer of the dielectric material 410). In some cases, forming the trench 430 may include removing a portion of each trench 425 and portions of the stack of materials 405 between each trench 425. Forming the trench 430 may include removing portions of the stack of materials 405 and the trenches 425 in accordance with a pattern. For example, a mask (e.g., a photolithographic mask) may be formed above the stack of materials 405 and the trenches 425, where the mask may selectively cover the stack of materials 405 and the trenches 425 such that the mask may expose the portions of the stack of materials 405 and the portions of the trenches 425 associated with the trench 430. In some such examples, the stack of materials 405 and the trenches 425 may be etched based on the mask, such that the portions of the stack of materials 405 and the trenches 425 exposed by the mask may be removed.

After forming the trench 430, at least a portion of the sacrificial material 415 may be removed from the stack of materials 405. That is, the sacrificial material 415 may be removed from the respective layers of the stack of materials 405 up to the end of the trenches 425 or the conductive material 445. In some cases, removing the sacrificial material 415 may include exhuming the sacrificial material 415 from the stack of materials 405 between the trenches 425. For example, the sacrificial material 415 may be selectively removed from the stack of materials 405 based on exposing the stack of materials 405 to an exhuming element associated with removing the sacrificial material 415 without removing other materials of the memory architecture.

After removing the sacrificial materials 415, channels 440 may be formed within the stack of materials 405. For example, the channels 440 may be formed based on removing the sacrificial material 415 from the stack of materials 405 and at least partially replacing the sacrificial material 415 with the channels 440. That is, the channels 440 may extend some direction along the y-direction at each layer of the stack of materials 405 otherwise associated with the sacrificial material 415. For example, the channels 440 may extend up to an end of the trenches 425 or the conductive material 445 and between the trenches 425.

After forming the channels 440, storage elements 435 may be deposited within the removed portions of the sacrificial material 415. For example, the storage elements 435 may be formed within the layers otherwise associated with the sacrificial material 415 and may extend to the channels 440, such that the storage elements 435 are adjacent to the channels 440 in the y-direction. Likewise, the storage elements 435 may be deposited up to the trench 430 in the y-direction. After forming the storage elements 435, the trench 430 may be filled with a conductive material 431. Filling the trench 430 with the conductive material 431 may be associated with forming a source line of the memory architecture. For example, forming the trench 430 may be associated with forming a source line 315 associated with accessing memory cells of the memory architecture, as described with reference to FIG. 3.

The memory cells of the memory architecture may be formed based on forming the storage element 435, the selection element, the word lines, the source line and the digit lines. For example, the memory cell may include the storage element 435 and the selection element configured to activate the storage element 435. However, the selection element may not access the storage element without activating the digit line, the word lines, and the source line associated with the storage element. Performing the processing steps 400 may be associated with manufacturing the memory architecture such that the memory cells are formed later in the manufacturing process. Forming the memory cells later in the manufacturing process may prevent a relatively high quantity of relatively high temperature manufacturing operations from being performed on the memory architecture after the formation of the memory cells. Thus, the memory cells may benefit from higher thermal budget sustainability, while maintaining relatively high channel controllability.

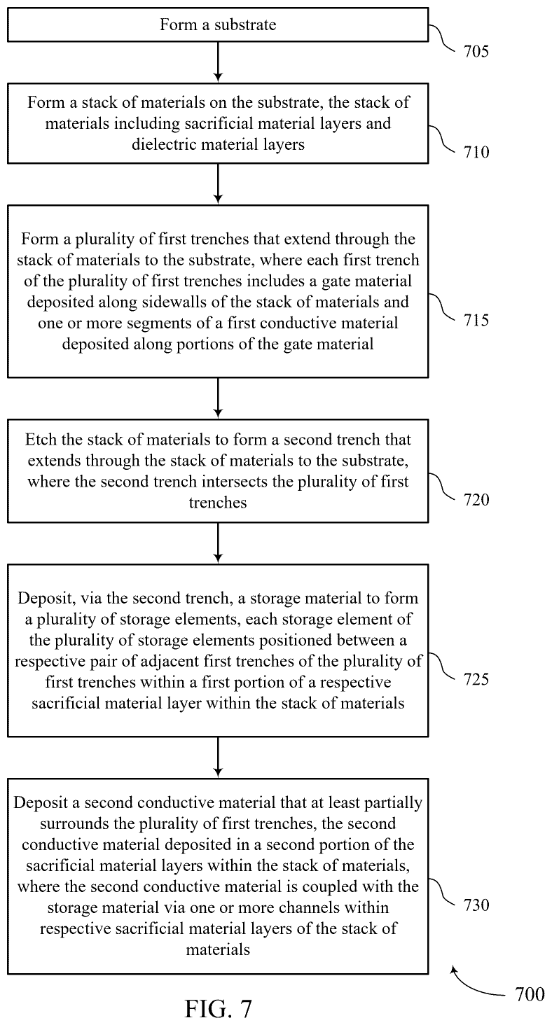

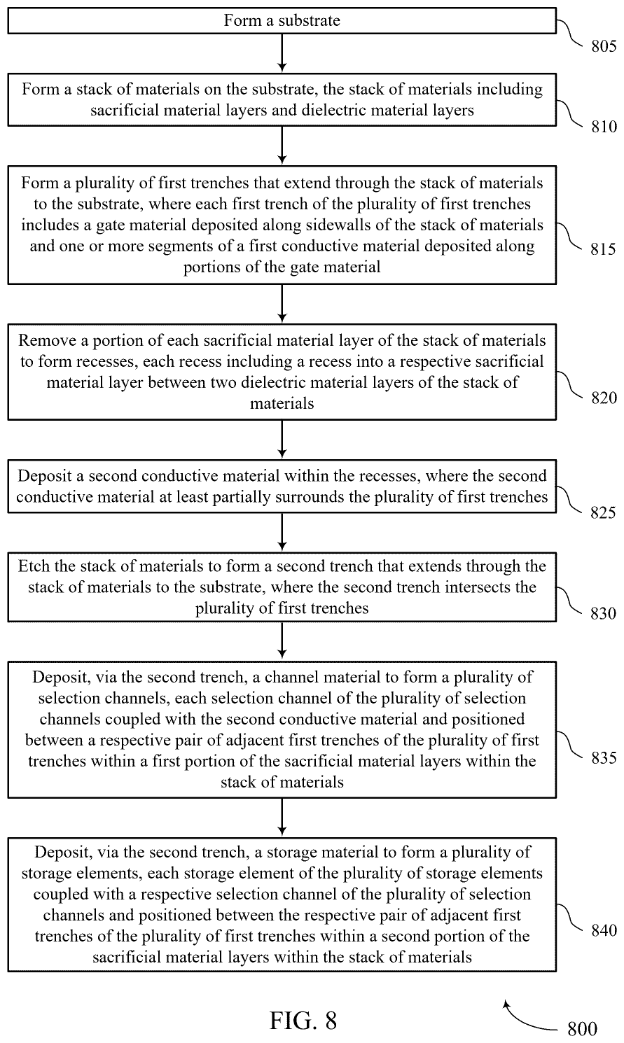

FIG. 7 shows a flowchart illustrating a method or methods 700 that supports replacement channel integration for three dimensional memory cell architectures in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 705, the method may include forming a substrate.

At 710, the method may include forming a stack of materials on the substrate, the stack of materials including sacrificial material layers and dielectric material layers.

At 715, the method may include forming a plurality of first trenches that extend through the stack of materials to the substrate, where each first trench of the plurality of first trenches includes a gate material deposited along sidewalls of the stack of materials and one or more segments of a first conductive material deposited along portions of the gate material.

At 720, the method may include etching the stack of materials to form a second trench that extends through the stack of materials to the substrate, where the second trench intersects the plurality of first trenches.

At 725, the method may include depositing, via the second trench, a storage material to form a plurality of storage elements, each storage element of the plurality of storage elements positioned between a respective pair of adjacent first trenches of the plurality of first trenches within a first portion of a respective sacrificial material layer within the stack of materials.

At 730, the method may include depositing a second conductive material that at least partially surrounds the plurality of first trenches, the second conductive material deposited in a second portion of the sacrificial material layers within the stack of materials, where the second conductive material is coupled with the storage material via one or more channels within respective sacrificial material layers of the stack of materials.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a substrate; forming a stack of materials on the substrate, the stack of materials including sacrificial material layers and dielectric material layers; forming a plurality of first trenches that extend through the stack of materials to the substrate, where each first trench of the plurality of first trenches includes a gate material deposited along sidewalls of the stack of materials and one or more segments of a first conductive material deposited along portions of the gate material; etching the stack of materials to form a second trench that extends through the stack of materials to the substrate, where the second trench intersects the plurality of first trenches; depositing, via the second trench, a storage material to form a plurality of storage elements, each storage element of the plurality of storage elements positioned between a respective pair of adjacent first trenches of the plurality of first trenches within a first portion of a respective sacrificial material layer within the stack of materials; and depositing a second conductive material that at least partially surrounds the plurality of first trenches, the second conductive material deposited in a second portion of the sacrificial material layers within the stack of materials, where the second conductive material is coupled with the storage material via one or more channels within respective sacrificial material layers of the stack of materials.

Aspect 2: The method or apparatus of aspect 1, further including operations, features, circuitry, logic, means, or instructions, or any combination thereof for removing, based at least in part on depositing the storage material, a third portion of the sacrificial material layers within the stack of materials to form a plurality of cavities within the sacrificial material layers, each cavity of the plurality of cavities between two dielectric material layers of the stack of materials and adjacent to a respective storage element of the plurality of storage elements; depositing, based at least in part on removing the third portion of the sacrificial material layers, a channel material in the plurality of cavities to form the one or more channels within the sacrificial material layers of the stack of materials; and where depositing the second conductive material is based at least in part on formation of the one or more channels.

Aspect 3: The method or apparatus of any of aspects 1 through 2, further including operations, features, circuitry, logic, means, or instructions, or any combination thereof for removing, via the second trench before depositing the storage material, a third portion of the sacrificial material layers within the stack of materials to form a plurality of cavities within the sacrificial material layers, each cavity of the plurality of cavities between two dielectric material layers of the stack of materials and adjacent to the second trench; depositing, based at least in part on removing the third portion of the sacrificial material layers, a channel material in the plurality of cavities to form the one or more channels within the sacrificial material layers of the stack of materials; and where depositing the storage material is based at least in part on depositing the one or more channels, the storage material deposited between the one or more channels and the second trench.

Aspect 4: The method or apparatus of any of aspects 1 through 3, further including operations, features, circuitry, logic, means, or instructions, or any combination thereof for removing, based at least in part on depositing the storage material, a fourth portion of the sacrificial material layers within the stack of materials to form a plurality of second cavities within the sacrificial material layers, each second cavity of the plurality of second cavities adjacent to the one or more channels within the sacrificial material layers and where depositing the second conductive material includes filling the plurality of second cavities with the second conductive material based at least in part on removing the fourth portion of the sacrificial material layers.

Aspect 5: The method or apparatus of any of aspects 1 through 4, where forming the plurality of first trenches includes operations, features, circuitry, logic, means, or instructions, or any combination thereof for forming a mask above the stack of materials, the mask exposing the stack of materials at areas associated with the plurality of first trenches and etching the stack of materials within the areas exposed by the mask based at least in part on forming the mask.

Aspect 6: The method or apparatus of aspect 5, further including operations, features, circuitry, logic, means, or instructions, or any combination thereof for depositing the gate material along the substrate and the sidewalls of the stack of materials within the plurality of first trenches; depositing the first conductive material along sidewalls of the gate material within the plurality of first trenches; forming a second mask above the stack of materials, the second mask exposing first portions of the gate material within the plurality of first trenches; and removing the first portions of the gate material exposed by the second mask based at least in part on forming the second mask, where the one or more segments of the first conductive material are located along second portions of the sidewalls of the gate material based at least in part on the second mask protecting the second portions of the sidewalls of the gate material.

Aspect 7: The method or apparatus of any of aspects 1 through 6, where forming the second trench includes operations, features, circuitry, logic, means, or instructions, or any combination thereof for forming a third mask above the stack of materials, the third mask exposing the stack of materials at a second area associated with the second trench and etching the stack of materials within the second area exposed by the third mask based at least in part on forming the third mask.

Aspect 8: The method or apparatus of any of aspects 1 through 7, further including operations, features, circuitry, logic, means, or instructions, or any combination thereof for forming one or more electrodes associated with each storage element of the plurality of storage elements, where each electrode is positioned between the respective pair of adjacent first trenches of the plurality of first trenches within the first portion of the respective sacrificial material layer within the stack of materials.

Aspect 9: The method or apparatus of any of aspects 1 through 8, where the second conductive material includes a plurality of digit lines stacked above the substrate, the plurality of digit lines coupled with a digit line decoder via a plurality of electrodes in a staircase region.

Aspect 10: The method or apparatus of any of aspects 1 through 9, where forming the stack of materials includes operations, features, circuitry, logic, means, or instructions, or any combination thereof for depositing the sacrificial material layers and the dielectric material layers in an alternating pattern along a first direction normal to the substrate.

FIG. 8 shows a flowchart illustrating a method 800 that supports replacement channel integration for three dimensional memory cell architectures in accordance with examples as disclosed herein. The operations of method 800 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 805, the method may include forming a substrate.

At 810, the method may include forming a stack of materials on the substrate, the stack of materials including sacrificial material layers and dielectric material layers.

At 815, the method may include forming a plurality of first trenches that extend through the stack of materials to the substrate, where each first trench of the plurality of first trenches includes a gate material deposited along sidewalls of the stack of materials and one or more segments of a first conductive material deposited along portions of the gate material.

At 820, the method may include removing a portion of each sacrificial material layer of the stack of materials to form recesses, each recess including a recess into a respective sacrificial material layer between two dielectric material layers of the stack of materials.

At 825, the method may include depositing a second conductive material within the recesses, where the second conductive material at least partially surrounds the plurality of first trenches.

At 830, the method may include etching the stack of materials to form a second trench that extends through the stack of materials to the substrate, where the second trench intersects the plurality of first trenches.

At 835, the method may include depositing, via the second trench, a channel material to form a plurality of selection channels, each selection channel of the plurality of selection channels coupled with the second conductive material and positioned between a respective pair of adjacent first trenches of the plurality of first trenches within a first portion of the sacrificial material layers within the stack of materials.

At 840, the method may include depositing, via the second trench, a storage material to form a plurality of storage elements, each storage element of the plurality of storage elements coupled with a respective selection channel of the plurality of selection channels and positioned between the respective pair of adjacent first trenches of the plurality of first trenches within a second portion of the sacrificial material layers within the stack of materials.

In some examples, an apparatus (e.g., a manufacturing system) as described herein may perform a method or methods, such as the method 800. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 11: A method or apparatus including operations, features, circuitry, logic, means, or instructions, or any combination thereof for forming a substrate; forming a stack of materials on the substrate, the stack of materials including sacrificial material layers and dielectric material layers; forming a plurality of first trenches that extend through the stack of materials to the substrate, where each first trench of the plurality of first trenches includes a gate material deposited along sidewalls of the stack of materials and one or more segments of a first conductive material deposited along portions of the gate material; removing a portion of each sacrificial material layer of the stack of materials to form recesses, each recess including a recess into a respective sacrificial material layer between two dielectric material layers of the stack of materials; depositing a second conductive material within the recesses, where the second conductive material at least partially surrounds the plurality of first trenches; etching the stack of materials to form a second trench that extends through the stack of materials to the substrate, where the second trench intersects the plurality of first trenches; depositing, via the second trench, a channel material to form a plurality of selection channels, each selection channel of the plurality of selection channels coupled with the second conductive material and positioned between a respective pair of adjacent first trenches of the plurality of first trenches within a first portion of the sacrificial material layers within the stack of materials; and depositing, via the second trench, a storage material to form a plurality of storage elements, each storage element of the plurality of storage elements coupled with a respective selection channel of the plurality of selection channels and positioned between the respective pair of adjacent first trenches of the plurality of first trenches within a second portion of the sacrificial material layers within the stack of materials.

Aspect 12: The method or apparatus of aspect 11, further including operations, features, circuitry, logic, means, or instructions, or any combination thereof for removing, via the second trench, the first portion of the sacrificial material layers within the stack of materials to form a plurality of cavities within the sacrificial material layers, each cavity of the plurality of cavities between two dielectric material layers of the stack of materials and adjacent to the second trench; depositing, based at least in part on removing the first portion of the sacrificial material layers, the channel material within the plurality of cavities to form the plurality of selection channels within the sacrificial material layers of the stack of materials; and where depositing the storage material is based at least in part on depositing the channel material.

Aspect 13: The method or apparatus of any of aspects 11 through 12, where forming the plurality of first trenches includes operations, features, circuitry, logic, means, or instructions, or any combination thereof for forming a mask above the stack of materials, the mask exposing the stack of materials at areas associated with the plurality of first trenches and etching the stack of materials within the areas exposed by the mask based at least in part on forming the mask.

Aspect 14: The method or apparatus of aspect 13, further including operations, features, circuitry, logic, means, or instructions, or any combination thereof for depositing the gate material along the substrate and the sidewalls of the stack of materials within the plurality of first trenches; depositing the first conductive material along sidewalls of the gate material within the plurality of first trenches; forming a second mask above the stack of materials, the second mask exposing first portions of the gate material within the plurality of first trenches; and removing the first portions of the gate material exposed by the second mask based at least in part on forming the second mask, where the one or more segments of the first conductive material are located along second portions of the sidewalls of the gate material based at least in part on the second mask protecting the second portions of the sidewalls of the gate material.

Aspect 15: The method or apparatus of any of aspects 11 through 14, where forming the second trench includes operations, features, circuitry, logic, means, or instructions, or any combination thereof for forming a third mask above the stack of materials, the third mask exposing the stack of materials at a second area associated with the second trench and etching the stack of materials within the second area exposed by the third mask based at least in part on forming the third mask.

Aspect 16: The method or apparatus of any of aspects 11 through 15, further including operations, features, circuitry, logic, means, or instructions, or any combination thereof for forming one or more electrodes associated with each storage element of the plurality of storage elements, where each electrode is positioned between the respective pair of adjacent first trenches of the plurality of first trenches within the first portion of the respective sacrificial material layer within the stack of materials.

Aspect 17: The method or apparatus of any of aspects 11 through 16, where the second conductive material includes a plurality of digit lines stacked above the substrate, the plurality of digit lines coupled with a digit line decoder via a plurality of electrodes in a staircase region.

Aspect 18: The method or apparatus of any of aspects 11 through 17, where forming the stack of materials includes operations, features, circuitry, logic, means, or instructions, or any combination thereof for depositing the sacrificial material layers and the dielectric material layers in an alternating pattern along a first direction normal to the substrate.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 19: An apparatus, including: a substrate; a plurality of digit lines stacked in a first direction above the substrate and coupled with a digit line decoder via a plurality of electrodes in a staircase region of the apparatus; a source line coupled with the substrate and that extends in the first direction above the substrate; and a plurality of pillars that extend in the first direction above the substrate, where each pillar of the plurality of pillars is coupled with the substrate, the plurality of digit lines, and the source line, and where each pillar of the plurality of pillars includes: a pair of conductive pillars that extend in the first direction above the substrate; a plurality of storage elements stacked in the first direction above the substrate and coupled with the source line; and a plurality of selection elements stacked in the first direction above the substrate and coupled with the pair of conductive pillars, where each of the plurality of selection elements is coupled with a respective digit line of the plurality of digit lines stacked in the first direction and with a respective storage element of the plurality of storage elements stacked in the first direction.

Aspect 20: The apparatus of aspect 19, where the pair of conductive pillars includes a gate of each selection element of the plurality of selection elements.

Aspect 21: The apparatus of any of aspects 19 through 20, where: a source of each selection element of the plurality of selection elements is coupled with the respective digit line of the plurality of digit lines; and a drain of each selection element of the plurality of selection elements is coupled with the respective storage element of the plurality of storage elements.

Aspect 22: The apparatus of any of aspects 19 through 21, where each selection element includes a channel of conductive material that extends, between the pair of conductive pillars, in a second direction within a respective layer of a plurality of layers of the apparatus stacked above the substrate.

Aspect 23: The apparatus of any of aspects 19 through 22, where each digit line of the plurality of digit lines extends in a second direction within a respective layer of a plurality of layers of the apparatus stacked above the substrate.

Aspect 24: The apparatus of aspect 23, further including: a second source line coupled with the substrate and extending in the first direction above the substrate; and a plurality of second pillars that extend in the first direction above the substrate, where each of the plurality of second pillars is coupled with the substrate, the plurality of digit lines, and the second source line, and where each digit line of the plurality of digit lines at least partially surrounds the plurality of pillars and the plurality of second pillars within the respective layer of the plurality of layers of the apparatus stacked above the substrate.

Aspect 25: The apparatus of any of aspects 19 through 24, where each storage element of the plurality of storage elements is positioned within a respective layer of a plurality of layers of the apparatus stacked above the substrate.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a substrate;
a plurality of digit lines stacked in a first direction above the substrate and coupled with a digit line decoder via a plurality of electrodes in a staircase region of the apparatus;
a source line coupled with the substrate and that extends in the first direction above the substrate; and
a plurality of pillars that extend in the first direction above the substrate, wherein each pillar of the plurality of pillars is coupled with the substrate, the plurality of digit lines, and the source line, and wherein each pillar of the plurality of pillars comprises:
a pair of conductive pillars that extend in the first direction above the substrate;
a plurality of storage elements stacked in the first direction above the substrate and coupled with the source line; and
a plurality of selection elements stacked in the first direction above the substrate and coupled with the pair of conductive pillars, wherein each of the plurality of selection elements is coupled with a respective digit line of the plurality of digit lines stacked in the first direction and with a respective storage element of the plurality of storage elements stacked in the first direction.

2. The apparatus of claim 1, wherein the pair of conductive pillars comprises a gate of each selection element of the plurality of selection elements.

3. The apparatus of claim 1, wherein:
a source of each selection element of the plurality of selection elements is coupled with the respective digit line of the plurality of digit lines; and
a drain of each selection element of the plurality of selection elements is coupled with the respective storage element of the plurality of storage elements.

4. The apparatus of claim 1, wherein each selection element comprises a channel of conductive material that extends, between the pair of conductive pillars, in a second direction within a respective layer of a plurality of layers of the apparatus stacked above the substrate.

5. The apparatus of claim 1, wherein each digit line of the plurality of digit lines extends in a second direction within a respective layer of a plurality of layers of the apparatus stacked above the substrate.

6. The apparatus of claim 5, further comprising:
a second source line coupled with the substrate and extending in the first direction above the substrate; and
a plurality of second pillars that extend in the first direction above the substrate, wherein each of the plurality of second pillars is coupled with the substrate, the plurality of digit lines, and the second source line, and wherein each digit line of the plurality of digit lines at least partially surrounds the plurality of pillars and the plurality of second pillars within the respective layer of the plurality of layers of the apparatus stacked above the substrate.

7. The apparatus of claim 1, wherein each storage element of the plurality of storage elements is positioned within a respective layer of a plurality of layers of the apparatus stacked above the substrate.

8. A method of manufacturing a memory device, comprising:
forming a substrate;
forming a stack of materials on the substrate, the stack of materials comprising sacrificial material layers and dielectric material layers;
forming a plurality of first trenches that extend through the stack of materials to the substrate, wherein each first trench of the plurality of first trenches comprises a gate material deposited along sidewalls of the stack of materials and one or more segments of a first conductive material deposited along portions of the gate material;
etching the stack of materials to form a second trench that extends through the stack of materials to the substrate, wherein the second trench intersects the plurality of first trenches;
depositing, via the second trench, a storage material to form a plurality of storage elements, each storage element of the plurality of storage elements positioned between a respective pair of adjacent first trenches of the plurality of first trenches within a first portion of a respective sacrificial material layer within the stack of materials; and
depositing a second conductive material that at least partially surrounds the plurality of first trenches, the second conductive material deposited in a second portion of the sacrificial material layers within the stack of materials, wherein the second conductive material is coupled with the storage material via one or more channels within respective sacrificial material layers of the stack of materials.

9. The method of claim 8, further comprising:
removing, based at least in part on depositing the storage material, a third portion of the sacrificial material layers within the stack of materials to form a plurality of cavities within the sacrificial material layers, each cavity of the plurality of cavities between two dielectric material layers of the stack of materials and adjacent to a respective storage element of the plurality of storage elements; and
depositing, based at least in part on removing the third portion of the sacrificial material layers, a channel material in the plurality of cavities to form the one or more channels within the sacrificial material layers of the stack of materials,
wherein depositing the second conductive material is based at least in part on formation of the one or more channels.

10. The method of claim 8, further comprising:
removing, via the second trench before depositing the storage material, a third portion of the sacrificial material layers within the stack of materials to form a plurality of cavities within the sacrificial material layers, each cavity of the plurality of cavities between two dielectric material layers of the stack of materials and adjacent to the second trench; and
depositing, based at least in part on removing the third portion of the sacrificial material layers, a channel material in the plurality of cavities to form the one or more channels within the sacrificial material layers of the stack of materials,
wherein depositing the storage material is based at least in part on depositing the one or more channels, the storage material deposited between the one or more channels and the second trench.

11. The method of claim 8, further comprising:
removing, based at least in part on depositing the storage material, a fourth portion of the sacrificial material layers within the stack of materials to form a plurality of second cavities within the sacrificial material layers, each second cavity of the plurality of second cavities adjacent to the one or more channels within the sacrificial material layers,
wherein depositing the second conductive material includes filling the plurality of second cavities with the second conductive material based at least in part on removing the fourth portion of the sacrificial material layers.

12. The method of claim 8, wherein forming the plurality of first trenches comprises:
forming a mask above the stack of materials, the mask exposing the stack of materials at areas associated with the plurality of first trenches; and
etching the stack of materials within the areas exposed by the mask based at least in part on forming the mask.

13. The method of claim 12, further comprising:
depositing the gate material along the substrate and the sidewalls of the stack of materials within the plurality of first trenches;
depositing the first conductive material along sidewalls of the gate material within the plurality of first trenches;
forming a second mask above the stack of materials, the second mask exposing first portions of the gate material within the plurality of first trenches; and
removing the first portions of the gate material exposed by the second mask based at least in part on forming the second mask, wherein the one or more segments of the first conductive material are located along second portions of the sidewalls of the gate material based at least in part on the second mask protecting the second portions of the sidewalls of the gate material.

14. The method of claim 8, wherein forming the second trench comprises:
forming a third mask above the stack of materials, the third mask exposing the stack of materials at a second area associated with the second trench; and
etching the stack of materials within the second area exposed by the third mask based at least in part on forming the third mask.

15. The method of claim 8, further comprising:
forming one or more electrodes associated with each storage element of the plurality of storage elements, wherein each electrode is positioned between the respective pair of adjacent first trenches of the plurality of first trenches within the first portion of the respective sacrificial material layer within the stack of materials.

16. The method of claim 8, wherein the second conductive material comprises a plurality of digit lines stacked above the substrate, the plurality of digit lines coupled with a digit line decoder via a plurality of electrodes in a staircase region.

17. The method of claim 8, wherein forming the stack of materials comprises:
depositing the sacrificial material layers and the dielectric material layers in an alternating pattern along a first direction normal to the substrate.

18. A method of manufacturing a memory cell architecture, comprising:
forming a substrate;
forming a stack of materials on the substrate, the stack of materials comprising sacrificial material layers and dielectric material layers;
forming a plurality of first trenches that extend through the stack of materials to the substrate, wherein each first trench of the plurality of first trenches comprises a gate material deposited along sidewalls of the stack of materials and one or more segments of a first conductive material deposited along portions of the gate material;
removing a portion of each sacrificial material layer of the stack of materials to form recesses, each recess comprising a recess into a respective sacrificial material layer between two dielectric material layers of the stack of materials;
depositing a second conductive material within the recesses, wherein the second conductive material at least partially surrounds the plurality of first trenches;
etching the stack of materials to form a second trench that extends through the stack of materials to the substrate, wherein the second trench intersects the plurality of first trenches;
depositing, via the second trench, a channel material to form a plurality of selection channels, each selection channel of the plurality of selection channels coupled with the second conductive material and positioned between a respective pair of adjacent first trenches of the plurality of first trenches within a first portion of the sacrificial material layers within the stack of materials; and
depositing, via the second trench, a storage material to form a plurality of storage elements, each storage element of the plurality of storage elements coupled with a respective selection channel of the plurality of selection channels and positioned between the respective pair of adjacent first trenches of the plurality of first trenches within a second portion of the sacrificial material layers within the stack of materials.

19. The method of claim 18, further comprising:
removing, via the second trench, the first portion of the sacrificial material layers within the stack of materials to form a plurality of cavities within the sacrificial material layers, each cavity of the plurality of cavities between two dielectric material layers of the stack of materials and adjacent to the second trench; and
depositing, based at least in part on removing the first portion of the sacrificial material layers, the channel material within the plurality of cavities to form the plurality of selection channels within the sacrificial material layers of the stack of materials,
wherein depositing the storage material is based at least in part on depositing the channel material.

20. The method of claim 18, wherein forming the plurality of first trenches comprises:
forming a mask above the stack of materials, the mask exposing the stack of materials at areas associated with the plurality of first trenches; and
etching the stack of materials within the areas exposed by the mask based at least in part on forming the mask.

21. The method of claim 20, further comprising:
depositing the gate material along the substrate and the sidewalls of the stack of materials within the plurality of first trenches;
depositing the first conductive material along sidewalls of the gate material within the plurality of first trenches;
forming a second mask above the stack of materials, the second mask exposing first portions of the gate material within the plurality of first trenches; and
removing the first portions of the gate material exposed by the second mask based at least in part on forming the second mask, wherein the one or more segments of the first conductive material are located along second portions of the sidewalls of the gate material based at least in part on the second mask protecting the second portions of the sidewalls of the gate material.

22. The method of claim 18, wherein forming the second trench comprises:
forming a third mask above the stack of materials, the third mask exposing the stack of materials at a second area associated with the second trench; and
etching the stack of materials within the second area exposed by the third mask based at least in part on forming the third mask.

23. The method of claim 18, further comprising:
forming one or more electrodes associated with each storage element of the plurality of storage elements, wherein each electrode is positioned between the respective pair of adjacent first trenches of the plurality of first trenches within the first portion of the respective sacrificial material layer within the stack of materials.

24. The method of claim 18, wherein the second conductive material comprises a plurality of digit lines stacked above the substrate, the plurality of digit lines coupled with a digit line decoder via a plurality of electrodes in a staircase region.

25. The method of claim 18, wherein forming the stack of materials comprises:
depositing the sacrificial material layers and the dielectric material layers in an alternating pattern along a first direction normal to the substrate.
